(19) United States
(12) Patent Application Publication
(10) Pub. No.: US 2026/0333660 A1
(43) Pub. Date: Oct. 22, 2026

(54) Semiconductor Device

(71) Applicant: Semiconductor Energy Laboratory Co., Ltd., Kanagawa-ken (JP)

(72) Inventors: Kouhei TOYOTAKA, Isehara, Kanagawa (JP); Yuto YAKUBO, Atsugi, Kanagawa (JP); Kazuma FURUTANI, Atsugi, Kanagawa (JP)

(73) Assignee: Semiconductor Energy Laboratory Co., Ltd., Kanagawa-ken (JP)

(21) Appl. No.: 19/115,660

(22) PCT Filed: Sep. 27, 2023
(86) PCT No.: PCT/IB2023/059583

§ 371 Date: Mar. 26, 2025

(30) Foreign Application Priority Data
Oct. 4, 2022 (JP) 2022-160483
Oct. 28, 2022 (JP) 2022-172952

(51) Int. Cl. H10B 12/00; G11C 11/4074; H10D 30/67; H10D 62/83

(52) U.S. Cl. CPC H10B 12/00; G11C 11/4074; H10D 30/6728; H10D 30/6731; H10D 30/6736; H10D 30/6757; H10D 62/83

(57) ABSTRACT

A novel semiconductor device is provided. The semiconductor device includes a flip-flop group including n flip-flops and a plurality of memory units. The flip-flop group has a function of retaining n-bit data. One of the plurality of memory units has a function of retaining n-bit data. Another one of the plurality of memory units has a function of retaining p-bit data. When n-bit data is retained in the flip-flop group, the n-bit data retained in the flip-flop group is written to the one of the memory units in a first operation. When p-bit data is retained in the flip-flop group, the p-bit data is written to the another memory unit in a second operation. Note that n is an integer greater than or equal to 2, and p is an integer greater than or equal to 1 and less than n.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting apparatus, a power storage device, a storage device (memory device), a driving method thereof, and a manufacturing method thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. In some cases, a storage device, a display device, a light-emitting apparatus, a lighting device, an electronic device, and the like themselves are semiconductor devices and also include a semiconductor device.

### BACKGROUND ART

The technology development of a semiconductor device that can retain electric charge corresponding to data by combining a transistor including an oxide semiconductor in a semiconductor layer where a channel is formed (also referred to as an “OS transistor”) and a transistor including silicon in a semiconductor layer where a channel is formed (also referred to as a “Si transistor”) has progressed.

The semiconductor device can achieve low power consumption owing to power gating or the like by having a structure of performing saving (“storing” or “backing up”) or loading (“restoring” or “recovering”) of a program or data retained in a flip-flop or the like. Thus, the application to a semiconductor device such as a CPU (Central Processing Unit) is progressing (see Patent Document 1, for example).

### REFERENCE

### Patent Document

[Patent Document 1] Japanese Published Patent Application No. 2013-9297

### SUMMARY OF THE INVENTION

### Problems to be Solved by the Invention

In a semiconductor device such as a CPU, when a request for an exceptional processing (also referred to as “interrupt processing”) is generated, data retained in a register is stored (written) to an external memory, and then the exceptional processing is executed. After the exceptional processing ends, the data stored in the external memory needs to be written back to the register. For example, in the case where a request for an exceptional processing such as an emergency stop is generated, long-term data storage may increase the possibility of occurrence of a significant problem. In addition, in the case where an exceptional processing request occurs with high frequency, the time taken for data storage and the time taken for writing back are too long to ignore. Thus, times for storing data and writing back the data are required to be shortened. In addition, in the case where the frequency of occurrence of an exceptional processing request is high, a large amount of energy is consumed to store and write back data between an external memory and a register, resulting in an increase in power consumption.

An object of one embodiment of the present invention is to provide a novel semiconductor device or the like. Another object is to provide a semiconductor device or the like with a reduced occupied area. Another object is to provide a semiconductor device or the like with reduced power consumption. Another object is to provide a highly reliable semiconductor device or the like. Another object is to provide a semiconductor device or the like with high arithmetic performance.

Note that the objects of one embodiment of the present invention are not limited to the objects listed above. The objects listed above do not preclude the existence of other objects. Note that the other objects are objects that are not described in this section and are described below. The objects that are not described in this section will be derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a semiconductor device including a flip-flop group including n (n is an integer greater than or equal to 2) flip-flops, a first memory unit including n memory circuits provided over the flip-flop group, and a second memory unit including p (p is an integer greater than or equal to 1 and less than n) memory circuits provided over the first memory unit. The flip-flop includes a first transistor including silicon in a semiconductor layer where a channel is formed. Each of the n memory circuits and the p memory circuits includes a second transistor including an oxide semiconductor in a semiconductor layer where a channel is formed. When data retained in the flip-flop group is a n-bit first data, the semiconductor device has a function of retaining the first data in the first memory unit in a first operation. When data retained in the flip-flop group is a p-bit second data, the second data is retained in the second memory unit in a second operation.

For example, each of the n memory circuits and the p memory circuits includes two second transistors and one capacitor. The two second transistors each preferably include a region overlapping with the capacitor. A vertical-channel transistor is preferably used as the second transistor. The flip-flop group has a function of retaining data greater than or equal to 1 bit and less than or equal to n bits.

The first operation is, for example, an operation due to a power gating. The second operation is, for example, an operation due to interrupt processing.

### Effect of the Invention

According to one embodiment of the present invention, a novel semiconductor device or the like can be provided. Alternatively, a semiconductor device or the like with a reduced occupied area can be provided. Alternatively, a semiconductor device or the like with reduced power consumption can be provided. Alternatively, a highly reliable semiconductor device or the like can be provided. Alternatively, a semiconductor device or the like with high arithmetic performance can be provided.

Note that the description of these effects does not preclude the existence of other effects. One embodiment of the present invention does not necessarily have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are diagrams illustrating structure examples of a semiconductor device.

FIG. 2A and FIG. 2B are diagrams illustrating structure examples of a semiconductor device.

FIG. 3A and FIG. 3B are diagrams illustrating structure examples of a semiconductor device.

FIG. 4A is a diagram illustrating a structure example of a semiconductor device. FIG. 4B is a timing chart showing an operation example of the semiconductor device.

FIG. 5A to FIG. 5E are diagrams illustrating operation examples of a semiconductor device.

FIG. 6 is a diagram showing an operation example of a semiconductor device.

FIG. 7A and FIG. 7B are diagrams illustrating structure examples of a semiconductor device.

FIG. 8A and FIG. 8B are diagrams illustrating structure examples of a semiconductor device.

FIG. 9 is a diagram illustrating a structure example of a semiconductor device.

FIG. 10 is a diagram illustrating a structure example of a semiconductor device.

FIG. 11 is a diagram showing an operation example of a semiconductor device.

FIG. 12 is a diagram showing an operation example of a semiconductor device.

FIG. 13A to FIG. 13C are diagrams illustrating a structure example of a semiconductor device.

FIG. 14A to FIG. 14E are diagrams illustrating structure examples of a semiconductor device.

FIG. 15A and FIG. 15B are diagrams illustrating structure examples of a semiconductor device.

FIG. 16A and FIG. 16B are diagrams illustrating structure examples of a semiconductor device.

FIG. 17A to FIG. 17D are diagrams illustrating a structure example of a semiconductor device.

FIG. 18 is a diagram illustrating a structure example of a semiconductor device.

FIG. 19 is a diagram illustrating a structure example of a semiconductor device.

FIG. 20A and FIG. 20B are diagrams illustrating structure examples of a semiconductor device.

FIG. 21A and FIG. 21B are diagrams illustrating structure examples of a semiconductor device.

FIG. 22A and FIG. 22B are diagrams illustrating a structure example of a semiconductor device.

FIG. 23A and FIG. 23B are diagrams illustrating a structure example of a semiconductor device.

FIG. 24A and FIG. 24B are diagrams illustrating a structure example of a semiconductor device.

FIG. 25 is a diagram illustrating a structure example of a semiconductor device.

FIG. 26 is a diagram illustrating a structure example of a semiconductor device.

FIG. 27A to FIG. 27J are diagrams illustrating examples of electronic devices.

FIG. 28A to FIG. 28C are diagrams illustrating examples of electronic devices.

FIG. 29 is a diagram illustrating an example of a device for space.

### MODE FOR CARRYING OUT THE INVENTION

Embodiments will be described below with reference to the drawings. However, the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, especially in a plan view (also referred to as a “top view”), a perspective view, and the like, the illustration of some components might be omitted for easy understanding of the invention. The illustration of some hidden lines and the like might also be omitted.

Unless otherwise specified, a transistor described in this specification and the like is an enhancement-mode (a normally-off mode) field-effect transistor. In the case where a transistor in this specification and the like is an n-channel transistor and unless otherwise specified, the threshold voltage (also referred to as “Vth”) of the transistor is higher than 0 V. In the case where the transistor in this specification and the like is a p-channel transistor and unless otherwise specified, the threshold voltage (also referred to as “Vth”) of the transistor is lower than or equal to 0 V. Unless otherwise specified, a plurality of transistors having the same conductivity type have the same Vth.

Unless otherwise specified, on-state current in this specification and the like refers to a drain current (also referred to as “Id”) of a transistor in an on state (also referred to as “conduction state”). Unless otherwise specified, an “on state” refers to a state where the voltage between a gate and a source (also referred to as “Vg” or “Vgs”) is higher than or equal to Vth in an n-channel transistor, and refers to a state where Vg is lower than or equal to the threshold voltage in a p-channel transistor. For example, the on-state current of an n-channel transistor sometimes refers to a drain current that flows when Vg is higher than or equal to Vth.

Unless otherwise specified, an off-state current in this specification and the like refers to an Id of a transistor in an off state (also referred to as a non-conduction state or a cut-off state). Unless otherwise specified, the off state of an n-channel transistor means that Vg is lower than Vth (in a p-channel transistor, Vg is higher than Vth). In this specification and the like, leakage current sometimes expresses the same meaning as off-state current.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is referred to as an oxide semiconductor in some cases. That is, an OS transistor can also be referred to as a transistor including a metal oxide or an oxide semiconductor.

Ordinal numbers such as “first” and “second” in this specification and the like are used in order to avoid confusion among components and do not denote any priority or sequence such as the sequence of steps or the stacking sequence. A term without an ordinal number in this specification and the like may be provided with an ordinal number in the SCOPE OF CLAIMS in order to avoid confusion among components. An ordinal number provided in this specification and the like and an ordinal number provided in the SCOPE OF CLAIMS might be different from each other. Furthermore, even when a term is provided with an ordinal number in this specification and the like, the ordinal number might be omitted in the SCOPE OF CLAIMS and the like.

In this specification and the like, the terms such as “electrode”, “wiring”, and “terminal” do not limit the functions of such components. For example, an “electrode” is used as part of a “wiring” in some cases, and vice versa. Furthermore, the terms “electrode” and “wiring” can also mean that a plurality of “electrodes” and “wirings” are provided in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, supply of a signal refers to supply of a predetermined potential to a wiring or the like. Thus, the term “signal” can be replaced with a term such as “potential” in some cases. A term such as “potential” can be replaced with the term “signal” in some cases. The “signal” may be a variable potential or a fixed potential. For example, it may be a power supply potential.

Note that the terms “film” and “layer” can be used interchangeably depending on the case or the circumstances. For example, the term “conductive layer” can be changed into the term “conductive film” in some cases. As another example, the term “insulating film” can be changed into the term “insulating layer” in some cases.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the term “one of a pair of terminals” is referred to as “one terminal” or a “first terminal” in some cases. The term “the other of the pair of terminals” is referred to as “the other terminal” or a “second terminal” in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

Functions of a “source” and a “drain” of a transistor are sometimes switched when a transistor of opposite polarity is used or when the direction of current flow is changed in circuit operation, for example. Therefore, the terms “source” and “drain” can be used interchangeably in this specification and the like.

In this specification and the like, a “gate” refers to part or the whole of a gate electrode and a gate wiring. A gate wiring refers to a wiring for electrically connecting at least one gate electrode of a transistor to another electrode or another wiring.

In this specification and the like, a “source” refers to part or the whole of a source region, a source electrode, and a source wiring. A source region refers to a region in a semiconductor layer, where the resistivity is lower than or equal to a given value. A source electrode refers to a conductive layer including a part connected to a source region. A source wiring refers to a wiring for electrically connecting at least one source electrode of a transistor to another electrode or another wiring.

In this specification and the like, a “drain” refers to part or the whole of a drain region, a drain electrode, and a drain wiring. A drain region refers to a region in a semiconductor layer, where the resistivity is lower than or equal to a given value. A drain electrode refers to a conductive layer including a part connected to a drain region. A drain wiring refers to a wiring for electrically connecting at least one drain electrode of a transistor to another electrode or another wiring.

In this specification and the like, the terms for describing positioning, such as “over”, “under” “above”, and “below”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “an electrode B over an insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “the electrode B overlapping with the insulating layer A” does not necessarily mean the state where the electrode B is formed over the insulating layer A, and does not exclude the state where the electrode B is formed under the insulating layer A and the state where the electrode B is formed on the right side (or the left side) of the insulating layer A.

Each of the terms “adjacent” and “proximity” in this specification and the like does not necessarily mean that a component is directly in contact with another component. For example, the expression “the electrode B adjacent to the insulating layer A” does not necessarily mean that the electrode B is formed in direct contact with the insulating layer A and does not exclude the case where another component is provided between the insulating layer A and the electrode B.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the terms “identical”, “the same”, “equal”, “uniform”, and the like (including synonyms thereof) used in describing calculation values and measurement values contain an error of ±20% unless otherwise specified.

In the drawings and the like related to this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with one another. More specifically, the X direction, the Y direction, and the Z direction are directions orthogonal to one another. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, in order to clarify a specific memory unit 255 from a plurality of memory units 255, the respective memory units 255 may be denoted as a memory unit 255[1], a memory unit 255 [2], a memory unit 255[3], and the like.

### Embodiment 1

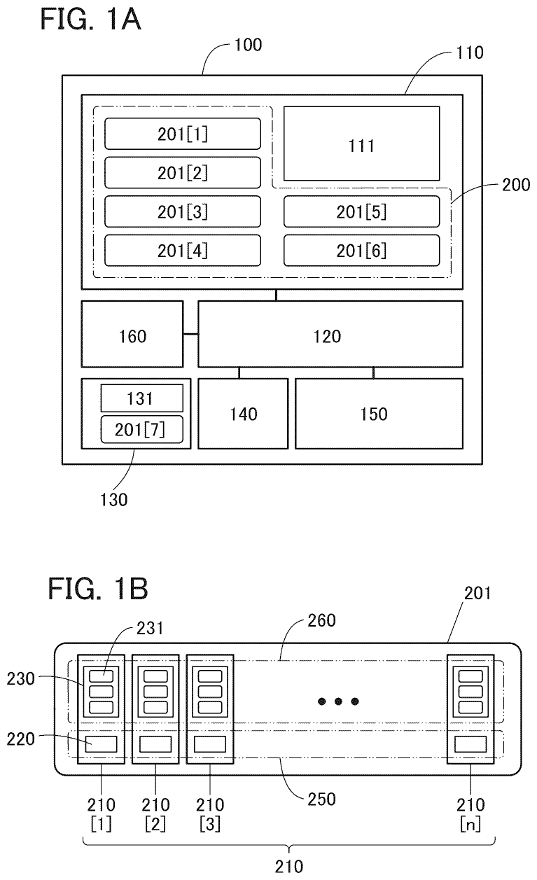

In this embodiment, structure examples of a semiconductor device of one embodiments of the present invention will be described. FIG. 1A is a block diagram illustrating a structure example of a semiconductor device 100.

The semiconductor device 100 illustrated in FIG. 1A includes a CPU core 110, a bus 120, a PMU (Power Management Unit) 130, an input/output IF 140, a cache memory 150, and a state control portion 160. The CPU core 110 includes an arithmetic portion 111 and a register group 200.

Note that the components of the semiconductor device 100 are not limited to the components illustrated in FIG. 1A and may include other components. Furthermore, some of the components illustrated in FIG. 1A may be excluded. One component may have a function of another component.

The register group 200 has a function of temporarily storing data used by the CPU core 110. The CPU core 110 has a function of performing arithmetic processing in the arithmetic portion 111 in accordance with data retained in the register group 200. The arithmetic portion 111 has a function of performing a variety of arithmetic operations such as four arithmetic operations and logic operations. The arithmetic portion 111 can also be referred to as an ALU (Arithmetic Logic Unit). The CPU core 110 is referred to as a processor core in some cases. One CPU core 110 may be provided in one semiconductor device 100 (single-core) or two or more CPU cores 110 may be provided in one semiconductor device 100 (multicore: e.g., dual-core or many-core).

The register group 200 includes a plurality of registers 201 (a register 201[1], a register 201[2], a register 201[3], a register 201[4], a register 201[5], and a register 201[6]). Note that the register 201 is a kind of storage device and is also a kind of semiconductor device.

The register 201[1] functions as a program counter, for example. The program counter has a function of storing a memory address indicating an instruction to be executed next. The register 201[2] functions as an instruction register, for example. The instruction register has a function of storing an instruction read from the memory. The register 201[3] functions as a base register, for example. The base register has a function of storing a start address of a program and data stored in a memory. The register 201[4] functions as, for example, an index register. The index register has a function of storing the size of data. The register 201[5] functions as an accumulator, for example. The accumulator has a function of temporarily storing the arithmetic operation result executed in the arithmetic portion 111. The register 201[6] functions as a general-purpose register, for example. The general-purpose register is not limited to be used for a particular application and is used for a variety of uses. For example, the register 201[6] may be used as an accumulator.

Note that all of the registers described above is not necessary included as the register 201 in the register group 200, and another register other than the above may be included. Alternatively, some or all kinds of the above registers 201 may be included, where each kind of registers is composed of a plurality of registers. For example, a plurality of the registers 201[6] functioning as general-purpose registers may be included.

The bus 120 has a function of controlling data transmission between the CPU core 110, the PMU 130, the input/output IF 140, the cache memory 150, and the state control circuit 160.

The PMU 130 includes a control circuit 131 and a register 201[7] and has a function of controlling execution and stop of power gating. Note that the register 201[7] is also a kind of the register 201. The register 201[7] functions as a setting register, for example. The setting register has a function of temporarily storing data used by the control circuit 131.

The input/output IF 140 has a function of controlling delivering data between an external device such as a main memory (not illustrated) and the semiconductor device 100. Data output from the external device is input to the semiconductor device 100 through the input/output IF 140. Data output from the semiconductor device 100 is input to the external device through the input/output IF 140. The cache memory 150 has a function of storing frequently used instructions, data, and the like and reducing the frequency of access to the main memory, thereby increasing the operation speed of the semiconductor device 100.

FIG. 1B is a block diagram showing a structure example of the register 201. The register 201 includes n (n is an integer greater than or equal to 2) OSFFs 210. In FIG. 1B, a first OSFF 210 is denoted by an OSFF 210[1], and an n-th OSFF 210 is denoted by an OSFF 210[n]. The OSFF 210 has a function of retaining 1-bit data. Thus, n corresponds to the data length that can be stored in the register 201 at a time. For example, in the register 201 capable of storing 64-bit data at a time, n is 64. Note that one OSFF 210 can also be referred to as the register 201 that can store 1-bit data.

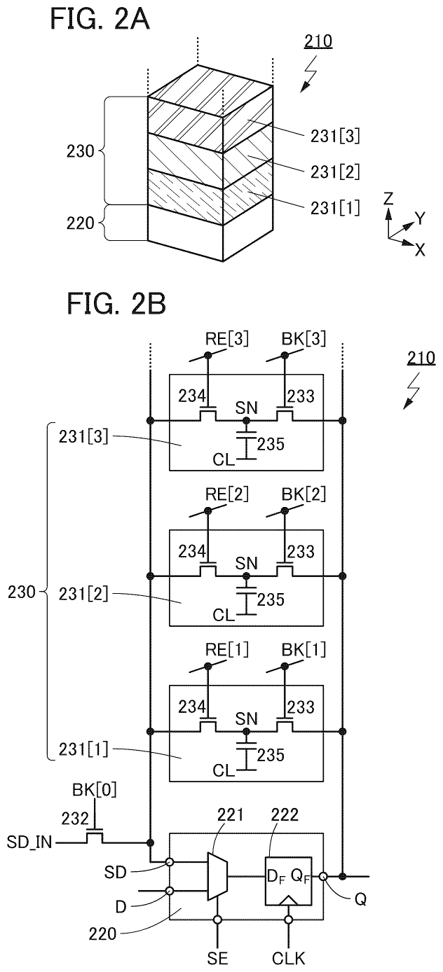

FIG. 2A is a perspective block diagram of the OSFF 210. FIG. 2B illustrates a circuit configuration example of the OSFF 210. The OSFF 210 includes a data retention circuit 230 over a scan flip-flop 220 (volatile register). The data retention circuit 230 includes a plurality of memory circuits 231. Although three memory circuits 231 (a memory circuit 231[1] to a memory circuit 231[3]) are stacked in this embodiment, the number of memory circuits 231 is not limited to three. All the scan flip-flops 220 included in the register 201 are collectively referred to as a flip-flop group 250 (see FIG. 1B). All the data retention circuits 230 included in the register 201 are collectively referred to as a bank memory 260. Thus, the bank memory 260 includes the plurality of memory circuits 231.

The scan flip-flop 220 includes a selector 221 and a flip-flop 222. The data retention circuit 230 includes the memory circuit 231. The OSFF 210 includes a transistor 232.

The state control portion 160 is a circuit that outputs a control signal for switching interrupt processing (also referred to as “excepting processing”) and power gating in accordance with signals such as an interrupt signal input from the outside and a sleep signal generated by the CPU core 110. The state control portion 160 generates a clock signal CLK and various signals (a signal BK, a signal RE, and a signal SE), for example. The clock signal CLK and the various signals are input to the CPU core 110.

The signal BK is a signal for controlling a saving of data retained in the flip-flop 222 in the scan flip-flop 220. By the data saving, the data retained in the flip-flop 222 is retained in any one of the plurality of memory circuits 231 in the data retention circuit 230. Note that in FIG. 2B, the signal BK supplied to the memory circuit 231[1] is denoted as a signal BK[1], the signal BK supplied to the memory circuit 231[2] is denoted as a signal BK[2], and the signal BK supplied to the memory circuit 231[3] is denoted as a signal BK[3].

The signal RE is a signal for controlling loading of data retained in any one of the plurality of memory circuits 231 in the data retention circuit 230. By the data loading, the data retained in any one of the plurality of memory circuits 231 in the data retention circuit 230 is retained in the flip-flop 222 in the scan flip-flop 220. Note that in FIG. 2B, the signal RE supplied to the memory circuit 231[1] is denoted as a signal RE[1], the signal RE supplied to the memory circuit 231[2] is denoted as a signal RE[2], and the signal RE supplied to the memory circuit 231[3] is denoted as a signal RE[3].

The signal SE is a switch signal for the selector 221. The clock signal CLK is a signal for determining the operation timing of the flip-flop 222.

The OSFF 210 has a function of retaining data input from a terminal D or data input from a terminal SD of the scan flip-flop 220 in the scan flip-flop 220 and outputting the data from a terminal Q in accordance with the clock signal CLK. Data in the scan flip-flop 220 output from the terminal Q is saved to any one of the plurality of memory circuits 231 included in the data retention circuit 230 in accordance with the signal BK. Data of any one of the plurality of memory circuits 231 included in the data retention circuit 230 is loaded into the scan flip-flop 220 from the terminal SD of the scan flip-flop 220 in accordance with the signal RE.

The selector 221 has a function of supplying one of a signal supplied in the terminal D and a signal supplied in the terminal SD to the flip-flop 222 in accordance with the signal SE. Data supplied from the outside of the OSFF 210 is input to the terminal D. Data input from the data retention circuit 230 or scan test data supplied through a terminal SD_IN is input to the terminal SD. The scan test data supplied through the terminal SD_IN is input to the terminal SD through the transistor 232. The conducting state or the non-conducting state of the transistor 232 is controlled by a signal BK[0].

Although the flip-flop 222 illustrated in FIG. 2B is a D flip-flop, the flip-flop 222 is not limited thereto. As the flip-flop 222, a flip-flop prepared in a standard circuit library can be used. A transistor included in the flip-flop 222 is a Si transistor where the CMOS circuit can be formed, and the flip-flop 222 can retain one piece of data by including a circuit such as an inverter loop. The flip-flop 222 retains data in an input terminal DF and outputs the retained data to the terminal Q through an output terminal QF in accordance with the clock signal CLK.

The plurality of memory circuits 231 are each connected to the terminal Q and the terminal SD. In each of the plurality of memory circuits 231, a terminal electrically connected to the terminal Q is referred to as an input terminal, and a terminal electrically connected to the terminal SD is referred to as an output terminal. The output terminal QF of the flip-flop 222 is electrically connected to an input terminal of the data retention circuit 230 (the memory circuit 231), and the input terminal DF of the flip-flop 222 is electrically connected to an output terminal of the data retention circuit 230 (the memory circuit 231) through the terminal SD and the selector 221.

Each of the plurality of memory circuits 231 includes a transistor 233, a transistor 234, and a capacitor 235. The transistor 233 is provided between one electrode of the capacitor 235 and the terminal Q. The transistor 234 is provided between the one electrode of the capacitor 235 and the terminal SD. In addition, the other electrode of the capacitor 235 is connected to a wiring CL. In each of the plurality of memory circuits 231, one electrode of the capacitor 235 is illustrated as a node SN.

OS transistors are preferably used as the transistor 233 and the transistor 234. The OS transistor has an extremely low off-state current, whereby the amount of charge retained at the node SN is not easily reduced and a voltage decrease of the node SN can be suppressed for a long period. In addition, electric power for retaining data (charge) written to the node SN is hardly needed. Thus, the memory circuit 231 included in the data retention circuit 230 can be regarded as a nonvolatile memory. Since the memory circuit 231 rewrites data by charging and discharging the capacitor 235, there is theoretically no limitation on rewrite cycles. In addition, data can be written and read at high speed with low energy.

A memory circuit formed using an OS transistor is also referred to as an “OS memory”. Thus, the memory circuit 231 is an OS memory.

Transistors having a back gate may be used as the transistor 233 and the transistor 234 may be used. By supplying a constant voltage to the back gate, Vth of the transistor can be controlled.

In the memory circuits 231, the OS transistors function as switches. In the OS transistor, which is an n-channel transistor, when a signal supplied to a gate is set to high level (hereinafter also referred to as “H”), a conduction state (on state) can be established between a source and a drain, and when the signal supplied to the gate is set to low level (hereinafter also referred to as “L”), a non-conduction state (off state) can be established between the source and the drain. Furthermore, when the signal SE is set to high level, a signal of the terminal SD is selected in the selector 221, and when the signal SE is set to low level, a signal of the terminal D is selected in the selector 221.

For example, when the signal BK[1] is set to H in the memory circuit 231[1], data retained in the flip-flop 222 can be written to the node SN in the memory circuit 231[1]. Similarly, when BK[2] is set to H and BK[3] is set to H, data in the flip-flop 222 can be written to the node SN of the memory circuit 231[2] and the node SN of the memory circuit 231[3]. Furthermore, when RE[1] is set to H and SE is set to H, the data in the node SN of the memory circuit 231[2] can be written back to the flip-flop 222. Similarly, when RE[2] is set to H and SE is set to H, the data in the node SN of the memory circuit 231[2] can be written back to the flip-flop 222. Similarly, when RE[3] is set to H and SE is set to H, data in the node SN of the memory circuit 231[3] can be written back to the flip-flop 222.

It is extremely preferable that all the transistors in the memory circuits 231 included in the data retention circuit 230 be OS transistors. The OS transistor is a kind of thin film transistor and can be formed to be stacked using an existing thin film formation technique. When the memory circuit 231 is formed using the OS transistor, the data retention circuit 230 can be stacked over the scan flip-flop 220 formed using a CMOS circuit using a Si transistor.

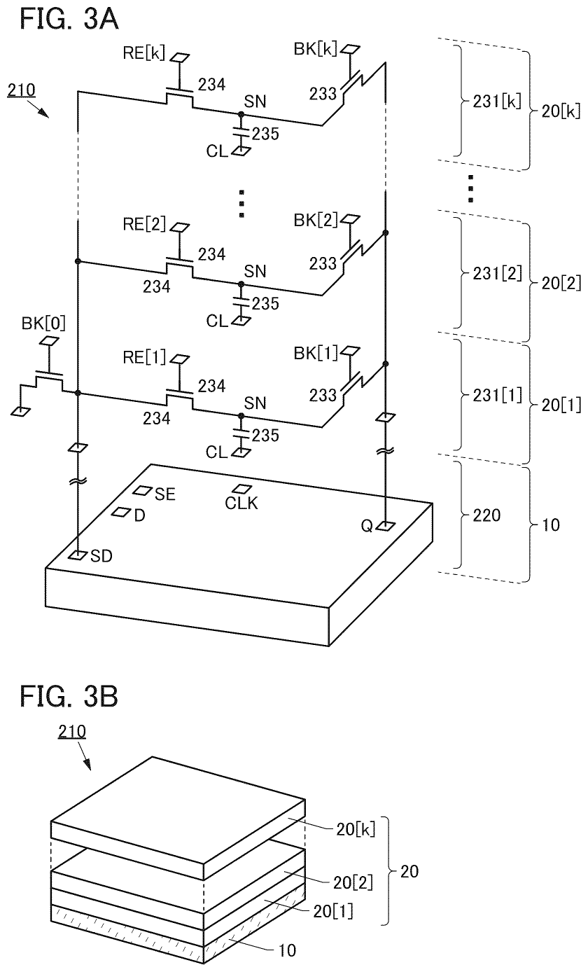

For example, as in the OSFF 210 illustrated in FIG. 3A, the plurality of memory circuits 231 can be stacked as different layers over the scan flip-flop 220 formed with a CMOS circuit using a Si transistor. Note that FIG. 3A illustrates the memory circuit 231[1], the memory circuit 231[2] to a memory circuit 231[k] (k is any one of integers greater than or equal to 2).

For example, as illustrated in FIG. 3A and FIG. 3B, the scan flip-flop 220 can be formed in a layer 10 including a Si transistor, and the data retention circuit 230 can be formed in a layer 20 including an OS transistor. That is, the flip-flop group 250 can be formed in the layer 10, and the bank memory 260 can be formed in the layer 20. The layer 20 can be formed with a plurality of layers. FIG. 3A and FIG. 3B illustrate an example in which the memory circuit 231[1] is formed in a layer 20[1], the memory circuit 231[2] is formed in a layer 20[2], and the memory circuit 231[k] is formed in the layer 20[k]. The signal BK supplied to the memory circuit 231[k] is referred to as a signal BK[k], and the signal RE supplied to the memory circuit 231[k] is referred to as a signal RE[k].

With this structure, the plurality of memory circuits 231 can be sequentially provided to overlap with a region where the scan flip-flop 220 is formed. Thus, even when the plurality of memory circuits 231 are incorporated, the area overhead of the OSFF 210 can be substantially zero. Thus, a semiconductor device that occupies a smaller area can be achieved.

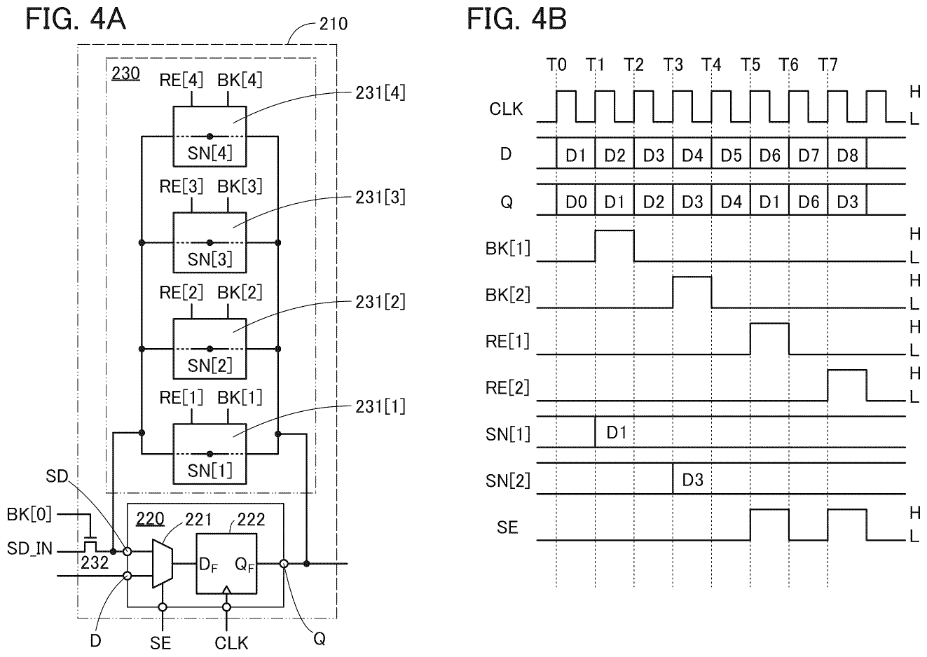

FIG. 4A illustrates a structure in which four (k=4) memory circuits 231 are included in the data retention circuit 230, which is used to describe the operation of the OSFF 210. In FIG. 4A, nodes SN[1] to SN[4] are illustrated as the node SN retaining data in the memory circuits 231 (the memory circuit 231[1] to the memory circuit 231[4]) included in the data retention circuit 230. Furthermore, in FIG. 4A, the signals BK[1] to BK[4] and the signals RE[1] to RE[4] that control the memory circuits 231[1] to 231[4] are illustrated.

FIG. 4B illustrates an example of a timing chart illustrating the operation of the OSFF 210 illustrated in FIG. 4A. Note that in FIG. 4B, T0 to T7 represent the time. FIG. 4B illustrates the clock signal CLK, the terminal D, the terminal Q, the signal BK[1], the signal BK[2], the signal RE[1], the signal RE[2], the node SN[1], the node SN[2], and the signal SE supplied to the selector 221. The flip-flop 222 saves data of the input terminal D and outputs the saved data from the output terminal Q in synchronization with a rising edge of the clock signal CLK (a waveform of the clock signal CLK switching from the L level to the H level).

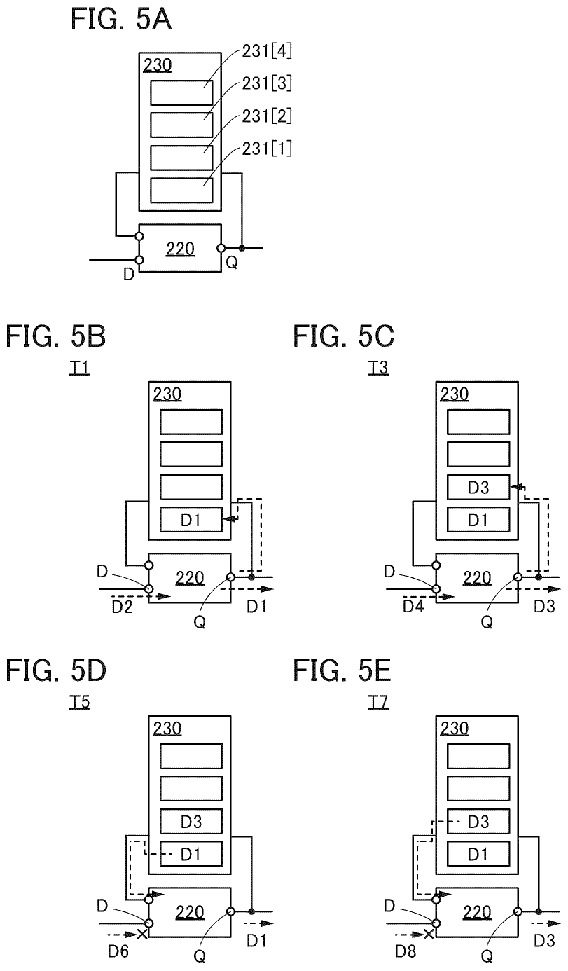

FIG. 5A to FIG. 5E are schematic diagrams of the OSFF 210 for explaining the operation in the timing chart in FIG. 4B. FIG. 5A illustrates the scan flip-flop 220 and the memory circuit 231[1] to the memory circuit 231[4] included in the data retention circuit 230. FIG. 5B, FIG. 5C, FIG. 5D, and FIG. 5E are diagrams illustrating data input to and output from the scan flip-flop 220 and 131[1] to the memory circuit 231[4] in the data retention circuit 230 at Time T1, Time T3, Time T5, and Time T7 in FIG. 4B.

At Time T0, the scan flip-flop 220 stores data D0 and outputs from the output terminal Q in synchronization with the rising edge of the clock signal CLK. Data D1 is supplied to the terminal D.

At Time T1, the scan flip-flop 220 retains the data D1 supplied to the terminal D and outputs the data D1 from the output terminal Q in synchronization with the rising edge of the clock signal CLK. At Time T1, the signal BK[1] is set to H, the signal RE[1] is set to L, and the signal SE is set to L, so that the data D1 output from the output terminal Q in the scan flip-flop 220 is retained in the memory circuit 231[1] (see FIG. 5B). Data D2 is supplied to the terminal D.

In addition, at Time T1, the signal BK[2] to the signal BK[4] and the signal RE[2] to the signal RE[4] are each at L.

At Time T2, the scan flip-flop 220 retains the data D2 supplied to the terminal D and outputs the data D2 from the output terminal Q in synchronization with the rising edge of the clock signal CLK. Data D3 is supplied to the terminal D.

At Time T3, the scan flip-flop 220 retains the data D3 supplied to the terminal D and outputs the data D3 from the output terminal Q in synchronization with the rising edge of the clock signal CLK. At Time T3, the signal BK[2] is set to H, the signal RE[2] is set to L, and the signal SE is set to L, so that the data D3 in the scan flip-flop 220 is retained in the memory circuit 231[2] (see FIG. 5C). Data D4 is supplied to the terminal D.

At Time T3, the signal BK[1], the signal BK[3], the signal BK[4], the signal RE[1], the signal RE[3], and the signal RE[4] are each at L.

At Time T4, the scan flip-flop 220 retains the data D4 supplied to the terminal D and outputs the data D4 from the output terminal Q in synchronization with the rising edge of the clock signal CLK. Data D5 is supplied to the terminal D.

At Time T5, BK[1] is set to L, RE[1] is set to H, and SE is set to H, so that the data D1 retained in the memory circuit 231[1] can be written back to the scan flip-flop 220 (see FIG. 5D). Data D6 is supplied to the terminal D.

In addition, at Time T5, the signal BK[2] to the signal BK[4] and the signal RE[2] to the signal RE[4] are each at L.

At Time T6, the scan flip-flop 220 retains the data D6 supplied to the terminal D and outputs the data D6 from the output terminal Q in synchronization with the rising edge of the clock signal CLK. Data D7 is supplied to the terminal D.

At Time T7, BK[2] is set to L, RE[2] is set to H, and SE is set to H, so that the data D3 retained in the memory circuit 231[2] can be written back to the scan flip-flop 220 (see FIG. 5E). Data D8 is supplied to the terminal D.

At Time T7, the signal BK[1], the signal BK[3], the signal BK[4], the signal RE[1], the signal RE[3], and the signal RE[4] are each at L.

As described with reference to FIG. 4B and FIG. 5B to FIG. 5E, the OSFF 210 can save data of the processing executed before the interrupt processing and can load the data of the processing resumed after the interrupt processing ends. In one embodiment of the present invention, the data saved in accordance with the switch of the interrupt processing can be retained in the plurality of memory circuits included in the data retention circuit. With this structure, data can be saved and loaded in accordance with the switch between multiple interrupt processing at the time when an interrupt signal is input. Thus, multiple interrupt processing can be sequentially executed. Thus, more efficient data processing can be achieved.

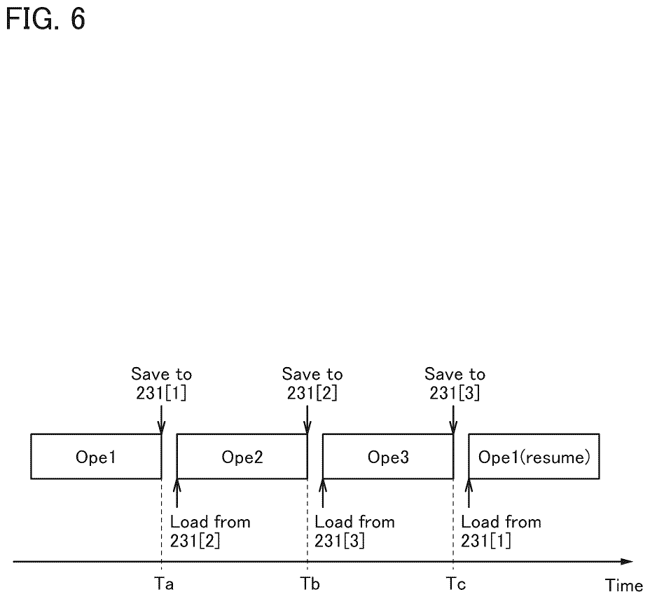

FIG. 6 is a timing chart of the operation of switching the interrupt processing of the semiconductor device 100 utilizing the OSFF 210 illustrated in FIG. 4A and the operation of the OSFF 210 illustrated in FIG. 4B; the horizontal axis represents a lapse of time (Time).

At Time Ta while the semiconductor device 100 is executing first processing (Ope 1), the data in the scan flip-flop 220 is saved to the memory circuit 231[1] (Save to 231[1]). Then, the data in the memory circuit 231[2] is written back to the scan flip-flop 220 (Load from 231[2]). In this manner, the semiconductor device 100 can interrupt the first processing and can execute second processing (Ope 2).

At Time Tb with the state where the semiconductor device 100 is executing the second processing, the data in the scan flip-flop 220 is saved to the memory circuit 231[2] (Save to 231[2]). Then, the data in the memory circuit 231[3] is written back to the scan flip-flop 220 (Load from 231[3]). In this manner, the semiconductor device 100 can interrupt the second processing and can execute third processing (Ope 3).

At Time Tc with the state where the semiconductor device 100 is executing the third processing, the data in the scan flip-flop 220 is saved in the memory circuit 231[3] (Save to 231[3]). Then, the data in the memory circuit 231[1] is written back to the scan flip-flop 220 (Load from 231[1]). Here, the data written back from the memory circuit 231[1] to the scan flip-flop 220 is the data saved to the memory circuit 231[1] from the scan flip-flop 220 at Time Ta. That is, the data is necessary for resuming the first processing interrupted at Time Ta. In this manner, the semiconductor device 100 can save the state of the third processing and then can restart the interrupted first processing.

With the use of the OSFF 210 of one embodiment of the present invention, it is possible to achieve a semiconductor device which can execute processing with high priority by interrupting processing being executed and restart the interrupted processing later. Thus, a semiconductor device with improved arithmetic performance can be provided.

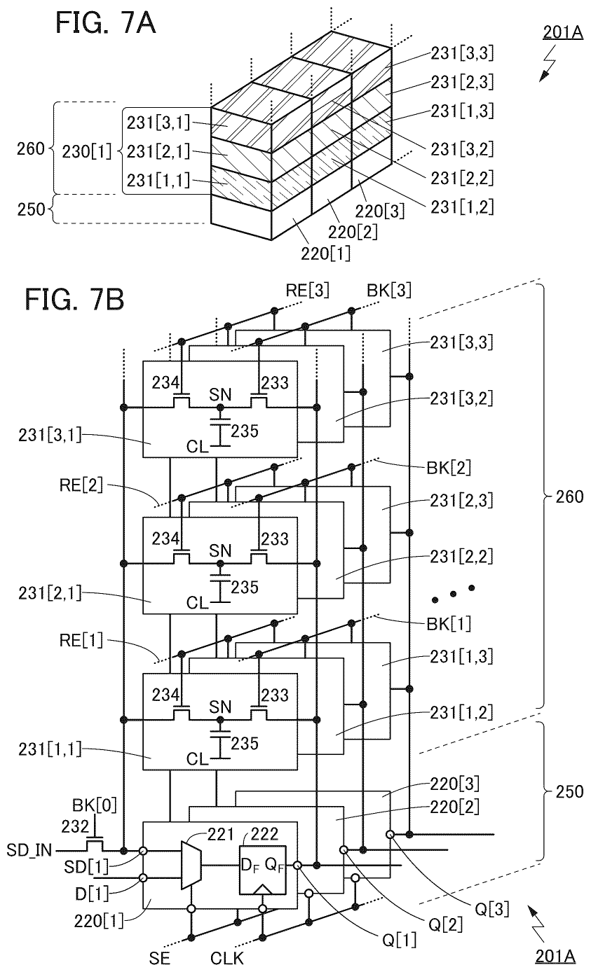

With a plurality of OSFFs 210, the register 201 which can temporarily store a plurality of pieces of multilevel data can be achieved. FIG. 7A is a perspective block diagram of a register 201A including three OSFFs 210 each including three memory circuits 231 illustrated in FIG. 2A. FIG. 7B is a diagram illustrating a circuit structure example of the register 201A illustrated in FIG. 7A.

The register 201A illustrated in FIG. 7A and FIG. 7B is the register 201 with n=3 and functions as the register 201 capable of storing 3-bit data at a time. Thus, the register 201A includes the flip-flop group 250 including three scan flip-flops 220 (a scan flip-flop 220[1], a scan flip-flop 220[2], and a scan flip-flop 220[3]). In FIG. 7A, the data retention circuit 230 provided over the scan flip-flop 220[1] is denoted as a data retention circuit 230[1].

In FIG. 7B, the terminal D and the terminal SD included in the scan flip-flop 220[1] are respectively denoted by a terminal D[1] and a terminal SD[1]. Note that the scan flip-flop 220[2] includes a terminal D[2] (not illustrated) as the terminal D and a terminal SD[2] (not illustrated) as the terminal SD. Similarly, the scan flip-flop 220[3] includes a terminal D[3] (not illustrated) as the terminal D and a terminal SD[3] (not illustrated) as the terminal SD.

In addition, the terminal Q of the scan flip-flop 220[1] is denoted by a terminal Q[1], the terminal Q of the scan flip-flop 220[2] is denoted by a terminal Q[2], and the terminal Q of the scan flip-flop 220[3] is denoted by a terminal Q[3].

In each of a memory circuit 231[1,1], a memory circuit 231[1,2], and a memory circuit 231[1,3] provided in a first layer (e.g., the layer 20[1]: see FIG. 3A and FIG. 3B) over the flip-flop group 250, the signal BK[1] is supplied to the gate of the transistor 233 and the signal RE[1] is supplied to the gate of the transistor 234. The memory circuit 231[1,1], the memory circuit 231[1,2], and the memory circuit 231[1,3] function as one memory circuit capable of storing 3-bit data.

In each of a memory circuit 231[2,1], a memory circuit 231[2,2], and a memory circuit 231[2,3] provided in a second layer (e.g., the layer 20[2]: see FIG. 3A and FIG. 3B) over the flip-flop group 250, the signal BK[2] is supplied to the gate of the transistor 233 and the signal RE[2] is supplied to the gate of the transistor 234. The memory circuit 231[2,1], the memory circuit 231[2,2], and the memory circuit 231[2,3] function as one memory circuit capable of storing 3-bit data.

In each of a memory circuit 231[3,1], a memory circuit 231[3,2], and a memory circuit 231[3,3] provided in a third layer over the flip-flop group 250, the signal BK[3] is supplied to the gate of the transistor 233 and the signal RE[3] is supplied to the gate of the transistor 234. The memory circuit 231[3,1], the memory circuit 231[3,2], and the memory circuit 231[3,3] function as one memory circuit capable of storing 3-bit data. A circuit that includes the plurality of memory circuits 231 and functions as one memory circuit is referred to as a “memory unit” in some cases.

Thus, the bank memory 260 of the register 201A illustrated in FIG. 7A and FIG. 7B includes three memory units which each can store 3-bit data. The register 201A illustrated in FIG. 7A and FIG. 7B can store data retained in the flip-flop group 250 to any of the memory units before power gating is executed. Even when the interrupt processing is performed three times in succession, data at each time of processing can be sequentially saved to different memory units. The backed-up data can be restored to the flip-flop group 250 every time the interrupt processing ends.

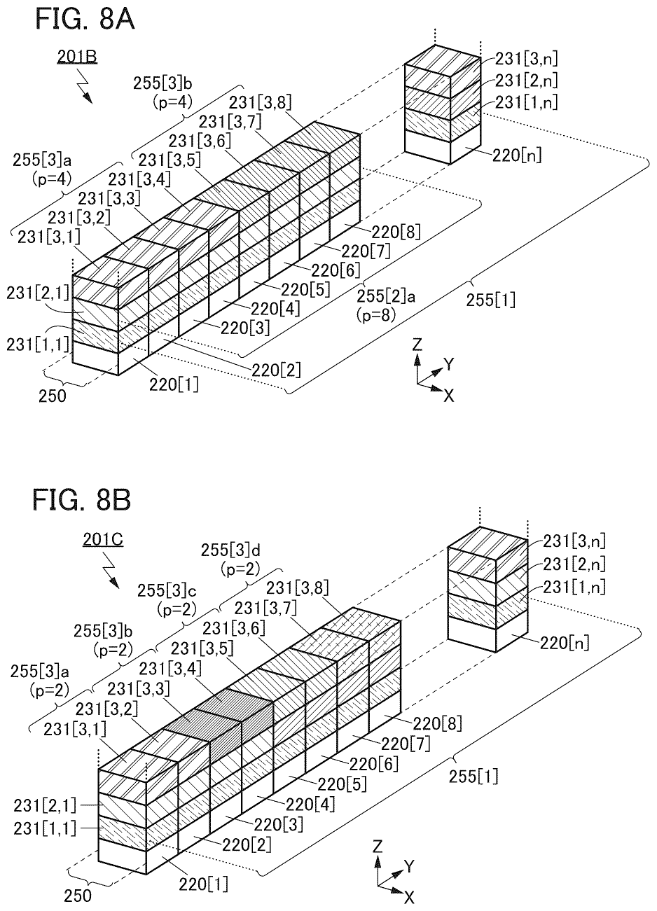

A register 201B illustrated in FIG. 8A and a register 201C illustrated in FIG. 8B are each the register 201 assuming that n is 9 or more, and function as the register 201 capable of storing n-bit data at a time.

Thus, the register 201B and the register 201C each include n scan flip-flops 220 (the scan flip-flop 220[1] to a scan flip-flop 220[n]) as the flip-flop group 250.

In addition, over the flip-flop group 250, n memory circuits 231 (the memory circuit 231[1,1] to a memory circuit 231[1,n]) are provided in the first layer, n memory circuits 231 (the memory circuit 231[2,1] to a memory circuit 231[2,n]) are provided in the second layer, and n memory circuits 231 (the memory circuit 231[3,1] to a memory circuit 231[3,n]) are provided in the third layer.

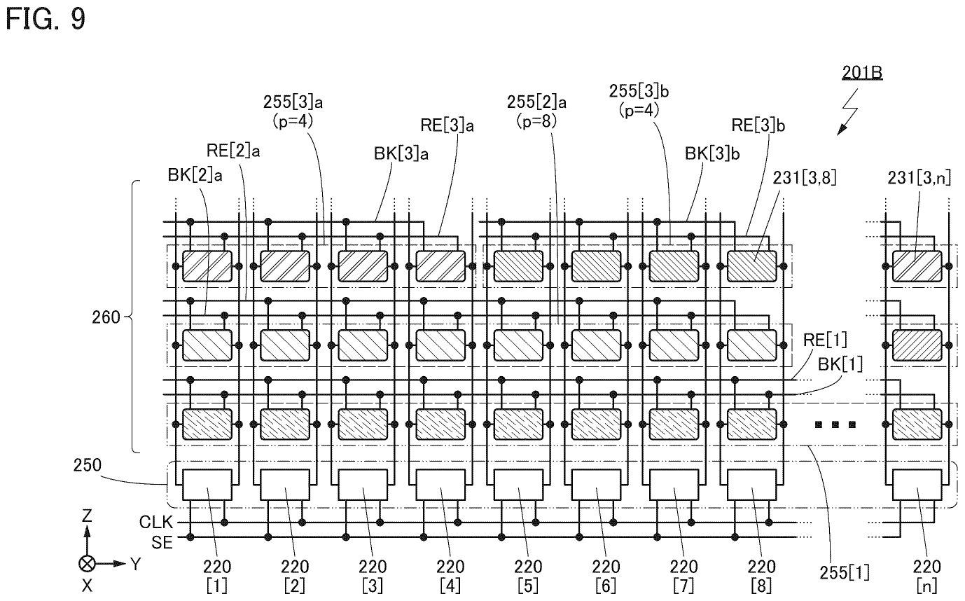

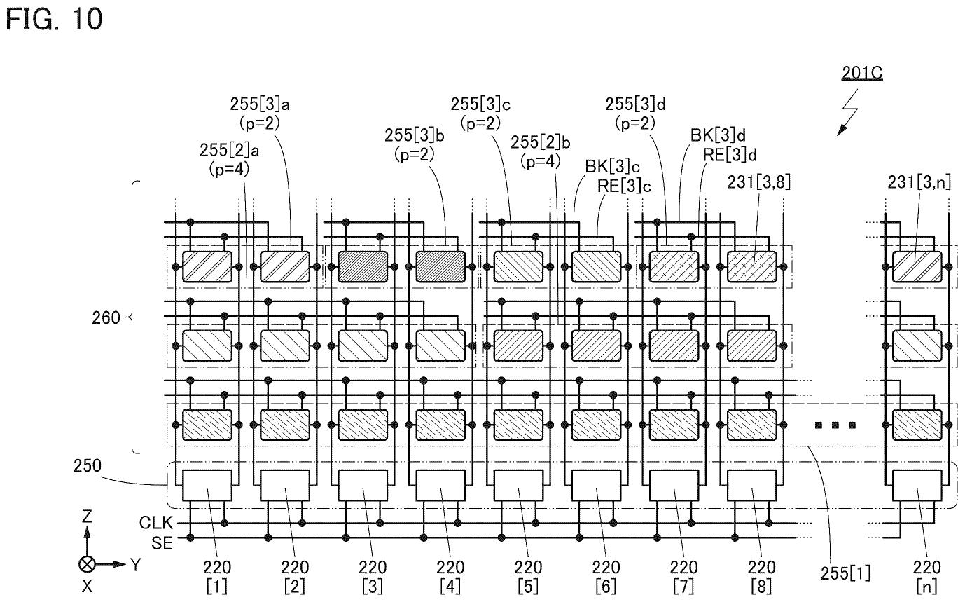

FIG. 9 is a block diagram of the register 201B seen from the X direction. FIG. 10 is a block diagram of the register 201C seen from the X direction. All the scan flip-flops 220 included in the register 201B are supplied with the signal SE at the same time or substantially at the same time and also supplied with the clock signal CLK at the same time or substantially at the same time. The register 201C has a similar structure. The register 201B and the register 201C each function as a register capable of storing n-bit data at a time in the flip-flop group 250.

Note that the register 201C is a variation example of the register 201B. In order to reduce the repetition of description, description of the register 201B and the register 201C can be replaced with each other unless otherwise specified.

The bank memory 260 includes a plurality of memory units 255 formed with the plurality of memory circuits 231. The plurality of memory units 255 may have the same storage capacity or different storage capacities.

The register 201B includes a memory unit 255[1] including n memory circuits 231 (the memory circuit 231[1,1] to the memory circuit 231[1,n]) formed in the first layer over the flip-flop group 250. The signal BK[1] and the signal RE[1] are supplied to all the memory circuits 231 included in the memory unit 255[1]. The memory unit 255[1] functions as a memory circuit with n-bit storage capacity. Note that the memory unit 255 with n-bit storage capacity is referred to as an “n-bit memory unit 255” in some cases.

The register 201B includes, as the memory unit 255, a memory unit 255 [2] including p memory circuits 231 formed in the second layer over the flip-flop group 250. Here, p is an integer greater than or equal to 1 and less than n. In the case of the memory unit 255[2] illustrated in FIG. 8A and FIG. 9, p which is the number of memory circuits 231 is 8. Thus, the memory unit 255[2] functions as a memory circuit with a 8-bit storage capacity. For example, in the case where n is 64 and p is 8, eight memory units 255[2] with a storage capacity of 8 bits can be formed in the second layer over the flip-flop group 250.

In FIG. 8A and FIG. 9, the first memory unit 255[2] is denoted by a memory unit 255[2]a. All of the memory circuits 231 included in a memory unit 255[1]a are supplied with a signal BK[2]a and a signal RE[2]a. The memory unit 255[2]a functions as a memory circuit with a storage capacity of 8 bits.

The register 201B includes, as the memory unit 255, a memory unit 255[3] including p memory circuits 231 formed in the third layer over the flip-flop group 250. In the case of the memory unit 255[3] illustrated in FIG. 8A and FIG. 9, p which is the number of memory circuits 231 is 4. Thus, the memory unit 255[3] functions as a memory circuit with a 4-bit storage capacity. For example, in the case where n is 64 and p is 4, 16 memory units 255[3] with a storage capacity of 4 bits can be formed in the third layer over the flip-flop group 250.

In FIG. 9, the first memory unit 255[3] including the memory circuit 231[3,1] to the memory circuit 231[3,4] (see FIG. 8A) is denoted by a memory unit 255[3]a, and the second memory unit 255[3] including memory circuit 231[3,5] to the memory circuit 231[3,8] (see FIG. 8A) is denoted by a memory unit 255[3]b. Signal BK[3]a and signal RE[3]a are supplied to all the memory circuits 231 included in the memory unit 255[3]a. Signal BK[3]b and signal RE[3]b are supplied to all the memory circuits 231 included in the memory unit 255[3]b. The memory unit 255[2]a and a memory unit 255[2]b each function as a memory circuit with a storage capacity of 4 bits.

In addition, as in the register 201C illustrated in FIG. 8B and FIG. 10, the memory unit 255[2] may include a plurality of memory units (the memory unit 255[2]a and the memory unit 255[2]b) in each of which the number of the memory circuits 231, p, is 4 and each of which functions as a four-bit memory circuit in the second layer over the flip-flop group 250. In addition, the memory unit 255[3] including two memory circuits 231 may be included in the third layer over the flip-flop group 250.

In the register 201C illustrated in FIG. 8B and FIG. 10, p which is the number of memory circuits 231 included in the memory unit 255 is 2. Thus, the memory unit 255[3] functions as a memory circuit with a storage capacity of 2 bits. For example, in the case where n is 64 and p is 2, 32 memory units 255[3] having a 2-bit of storage capacity can be formed in the third layer over the flip-flop group 250.

In FIG. 10, the first memory unit 255[3] including the memory circuit 231[3,1] and the memory circuit 231[3,2] (see FIG. 8B) is denoted by the memory unit 255[3]a, the second memory unit 255[3] including the memory circuit 231[3,3] and the memory circuit 231[3,4] (see FIG. 8B) is denoted by the memory unit 255[3]b, the second memory unit 255[3] including the memory circuit 231[3,5] and the memory circuit 231[3,6] (see FIG. 8B) is denoted by a memory unit 255[3]c, and the second memory unit 255[3] including the memory circuit 231[3,7] and the memory circuit 231[3,8] (see FIG. 8B) is denoted by a memory unit 255[3]d.

All the memory circuits 231 included in the memory unit 255[3]a are supplied with the signal BK[3]a and the signal RE[3]a, all the memory circuits 231 included in the memory unit 255[3]b are supplied with the signal BK[3]b and the signal RE[3]b, all the memory circuits 231 included in the memory unit 255[3]c are supplied with signal BK[3]c and signal RE[3]c, and all the memory circuits 231 included in the memory unit 255[3]d are supplied with signal BK[3]d and signal RE[3]d. The memory unit 255[3]a to the memory unit 255[3]d each function as a memory circuit with a storage capacity of 2 bits.

The storage capacity of the memory unit 255 is not limited to the above. The storage capacity of the memory unit 255 may be 32 bits or 16 bits. Alternatively, the storage capacity may be 9 bits or 17 bits depending on the purpose or the like.

In this embodiment, an example in which the n-bit memory unit 255 is provided in the first layer (e.g., the layer 20[1]: see FIG. 3A and FIG. 3B.) over the flip-flop group 250 is shown, but the n-bit memory unit 255 may be provided in a layer other than the first layer. For example, the n-bit memory unit 255 may be provided in the layer 20[2] or in the layer 20[k].

The number of digits of data represented in binary numbers is referred to as “bit length” or “data length” in some cases. The memory units 255 having different storage capacity may be provided in the same layer. For example, a 32-bit memory unit 255 where p is 32, a 16-bit memory unit 255 where p is 16, and an 8-bit memory unit 255 may be provided in the same layer. That is, the plurality of memory units 255 that can store data with different bit lengths may be provided in the same layer.

Since the size of data (bit length) retained in the register 201 may vary depending on the processing to be executed, the size is not always the same. For example, when 32-bit data is saved in the 64-bit memory unit 255, an unnecessary saving operation is performed for the remaining 32-bit storage capacity. Thus, unnecessary power consumption is caused. When the bank memory 260 includes the memory units 255 with a variety of storage capacities data with different sizes can be efficiently saved. Thus, the power consumption of the register 201 can be reduced.

When the memory units 255 with different storage capacities are used in combination, data with a variety of sizes can be efficiently saved. For example, by combining the 4-bit memory unit 255 where p is 4 and the 8-bit memory unit 255 where p is 4, 12-bit data can be saved.

At the time of performing power gating, all data (n-bit data) in the scan flip-flop 220 needs to be backed up. At this time, n-bit data stored in the scan flip-flop 220 may be divided into a plurality of pieces to be saved in the plurality of memory units 255.

Meanwhile, in order to divide n-bit data into a plurality of pieces of data and save the data, for example, the following steps are needed: a step of searching for a plurality of usable memory units 255, a step of checking the storage capacities of each of the plurality of usable memory units 255, a step of determining the dividing position of the n-bit data to be saved, and a step of actually performing a saving. This takes time to start power gating and restore the data, resulting in unnecessary power consumption.

Thus, at least one of the plurality of memory units 255 is preferably the memory unit 255 with a storage capacity of n-bit. That is, at least one of the plurality of memory units 255 preferably has the same storage capacity as the memory unit 255 in the register 201B.

As described above, in the semiconductor device of this embodiment, even when interrupt processing occurs during the program processing and another interrupt processing further occurs, the original processing can be restarted on the basis of data immediately before the execution of the interrupt processing. Data for restarting the processing which is interrupted is retained in the register group 200 in the CPU core 110. Thus, there is no need to access an external memory such as an SRAM or a DRAM to save or load data. Thus, saving and loading data, accompanying the execution of the interrupt processing and the restart of the interrupted processing, can be performed efficiently without time lag.

The structure described in this embodiment can be used in an appropriate combination with the structures described in the other embodiments.

### Embodiment 2

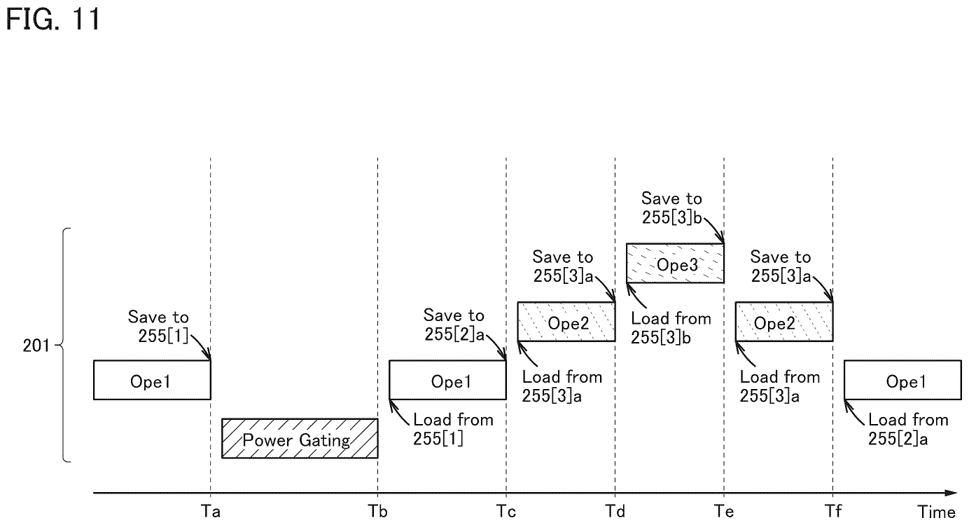

In this embodiment, an operation example of the semiconductor device 100 of to one embodiment of the present invention will be described. As described above, the semiconductor device 100 includes the register 201 of one embodiment of the present invention (see FIG. 1). Note that the register 201 exemplified in this embodiment is a register capable of storing 64-bit data in the flip-flop group 250. FIG. 11 is a timing chart showing operation states of the semiconductor device 100 and the register 201, and the horizontal axis represents passage of time (Time).

### Time Ta

In a state where the semiconductor device 100 is executing the first processing (Ope 1), a signal for performing power gating is supplied from the CPU core 110 to the state control portion 160 through the input/output IF 140 at Time Ta.

The state control portion 160 saves 64-bit data retained in the flip-flop group 250 of the register 201 to the memory unit 255 with a storage capacity of 64-bit included in the register 201. For example, the data is saved to the memory unit 255[1] with a storage capacity of 64-bit (Save to 255[1]).

The register 201 of one embodiment of the present invention can save all 64-bit data to the memory unit 255[1] when the signal BK[1] is set to L (see FIG. 2B and FIG. 9). In other words, data can be backed up by an one-clock operation; thus, data can be quickly backed up.

Furthermore, the state control portion 160 supplies a signal for stopping power supply to the PMU 130. The whole CPU core 110 may undergo the stop of power supply or part of the CPU core 110 may undergo the stop of power supply. For example, all the registers 201 included in the register group 200 may undergo the stop of power supply, or some of the registers 201 may undergo the stop of power supply.

In this manner, the semiconductor device 100 comes into the power gating state. Note that even in the power gating state, the semiconductor device 100 does not stop supplying power to circuits and the like that are needed for resuming power supply in a later step.

### Time Tb

At Time Tb, the CPU core 110 supplies a signal that ends power gating to the state control portion 160 through the input/output IF 140. The state control portion 160 supplies a signal for restarting power supply to the PMU 130.

After the power supply is restarted, the state control portion 160 makes the flip-flop group 250 of the register 201 read data retained in the memory unit 255[1] of the register 201 (Load from 255[1]). After that, the semiconductor device 100 restarts the first processing interrupted at Time Ta. In this manner, the semiconductor device 100 transitions from a power gating state to a normal active state (Active).

The register 201 of one embodiment of the present invention can restore all 64-bit data to the flip-flop group 250 from the memory unit 255[1] when the signal RE[1] is set to H while the signal BK[1] remains at L and then the signal SE is set to H. In other words, data can be restored in a two-clock operation; thus, quick data restoration can be achieved.

### Time Tc

While the semiconductor device 100 is executing the first processing (Ope 1), a signal for preparation for execution of the second processing (Ope 2), which is interrupt processing, is supplied to the state control portion 160 from the CPU core 110 or through the input/output IF 140 at Time Tc.

In accordance with the bit length of data retained in the flip-flop group 250 of the register 201, the state control portion 160 determines the memory unit 255 to which the data is saved. For example, in the case where the bit length of the data is 8 bits, the data is saved to the memory unit 255[2]a with a storage capacity of 8 bits (Save to 255[2]a).

Note that in the case where there is no room in the memory unit 255 with the same bit length as the data to be saved, the data may be saved in the memory unit 255 with a larger bit length than the data. Alternatively, the data may be divided and saved into the plurality of memory units 255 each having a smaller bit length than the data.

Next, data necessary for execution of the second processing is read from the memory unit 255[3]a (Load from 255[3]a). Note that data necessary for execution of the second processing may be read from the cache memory 150 or supplied from the outside through the input/output IF 140. After data necessary for execution of the second processing is read, the semiconductor device 100 executes the second processing.

### Time Td

While the semiconductor device 100 is executing the second processing, a signal for preparation for execution of the third processing (Ope 3), which is interrupt processing, is supplied to the state control portion 160 from the CPU core 110 or through the input/output IF 140 at Time Td.

In accordance with the bit length of data retained in the flip-flop group 250 of the register 201, the state control portion 160 determines the memory unit 255 to which the data is saved. For example, in the case where the bit length of the data is 4 bits, the data is saved to the memory unit 255[3]a with a storage capacity of 4 bits (Save to 255[3]a).

Next, data necessary for execution of the third processing is read from the memory unit 255[3]b (Load from 255[3]b). Note that data necessary for execution of the third processing may be read from the cache memory 150 or supplied from the outside through the input/output IF 140. After data necessary for execution of the third processing is read, the semiconductor device 100 executes the third processing.

### Time Te

At Time Te, the third processing is assumed to be ended. After the third processing is ended, data retained in the flip-flop group 250 of the register 201 may be saved in the memory unit 255 (Save to 255[3]b).

After the third processing is ended, data saved in the memory unit 255[3]a is read to restart the interrupted second processing (Load from 255[3]a). After data necessary for execution of the second processing is read, the semiconductor device 100 restarts the interrupted second processing.

### Time Tf

At Time Tf, the second processing is assumed to be ended. After the second processing is ended, data retained in the flip-flop group 250 of the register 201 may be saved in the memory unit 255 (Save to 255[3]a).

After the second processing is ended, data saved in the memory unit 255[2]a is read to restart the interrupted first processing (Load from 255[2]a). After data necessary for execution of the first processing is read, the semiconductor device 100 restarts the interrupted first processing.

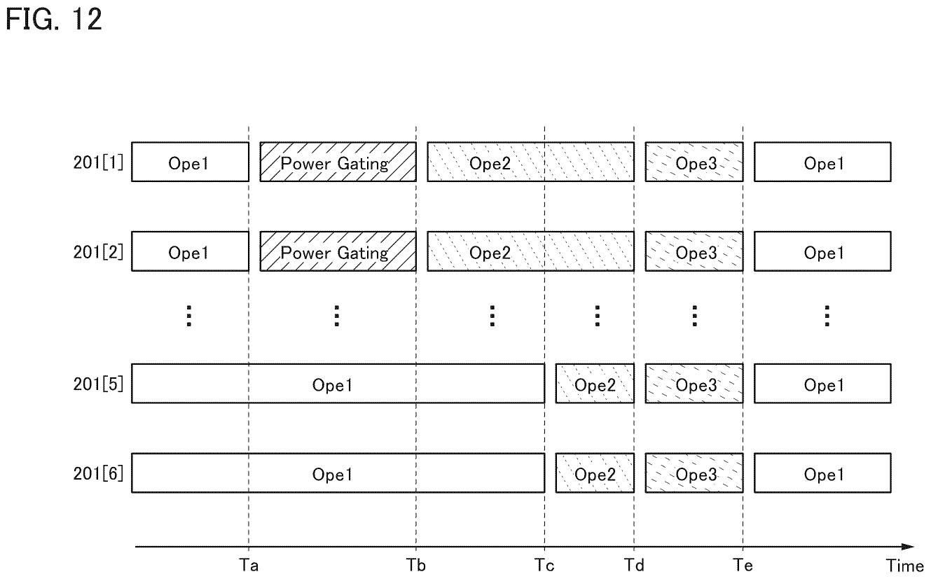

The register 201[1], the register 201[2], the register 201[3], the register 201[4], the register 201[5], and the register 201[6] included in the CPU core 110 may perform different processing from each other. For example, as shown in a timing chart in FIG. 12, only the register 201[1] and the register 201[2] may be in the power gating state in the period from Time Ta to Time Tb. In a period from Time Tb to Time Tc, data for performing the second processing may be retained in the register 201[1] and the register 201[2], and data for performing the first processing may be retained in the register 201[5] and the register 201[6].

The memory unit 255 is formed using an OS memory, and thus can perform data writing and reading at high speed with low energy. Thus, just before the transition to the power gating state, data retained by the flip-flop group 250 can be stored to the memory unit 255 included in the bank memory 260 in a short time. In addition, the data stored in the memory unit 255 can be retained even in the power gating state. In addition, in the case of returning from the power gating state to the active state, the data in the memory unit 255 can be written back to the flip-flop group 250 in a short time; thus, the processing can be immediately restarted.

In addition, data can be backed up (written) and restored (read) at high speed and with low energy even on the occurrence of the interrupt processing. When the bank memory 260 includes the plurality of memory units 255 with different storage capacities, data with different bit lengths can be stored efficiently. That is, the efficiency of use of the bank memory 260 can be increased.

The structure described in this embodiment can be used in an appropriate combination with the structures described in the other embodiments.

### Embodiment 3

In this embodiment, stacked-layer structure examples of the semiconductor device of embodiments of the present invention will be described.

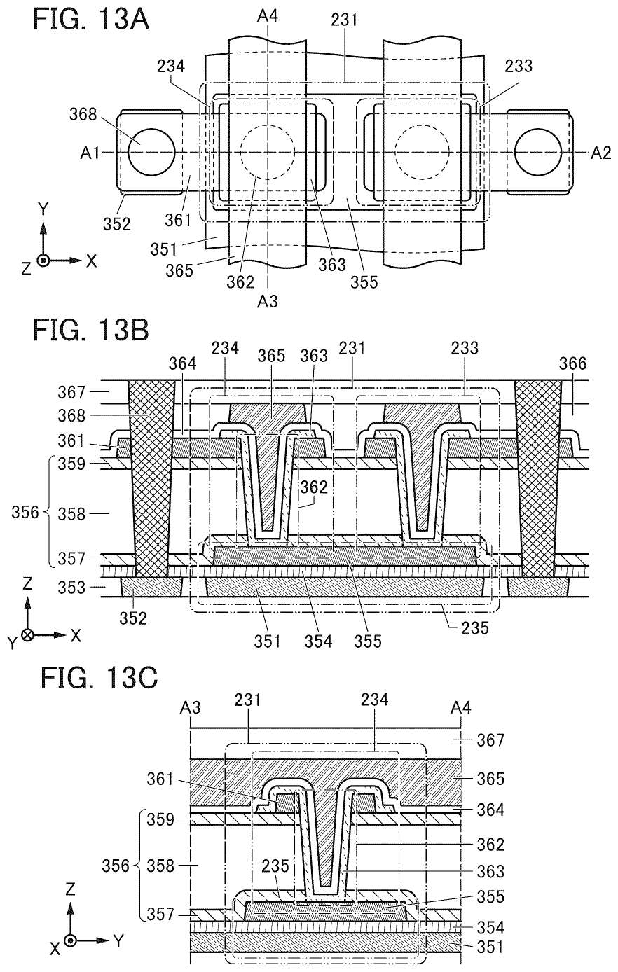

FIG. 13A is a plan view of the memory circuit 231, which is a kind of semiconductor device, seen from the Z direction. FIG. 13B is a cross-sectional view of a portion indicated by the dashed-dotted line A1-A2 in FIG. 13A, which is seen in the Y direction. FIG. 13C is a cross-sectional view of a portion indicated by the dashed-dotted line A3-A4 in FIG. 13A, which is seen from the X direction. Note that for clarity of the drawing, some components are omitted in the plan view of FIG. 13A. Note that in this embodiment and the like, the stacking direction of the layers included in the semiconductor device is referred to as the Z direction.

The memory circuit 231, which is a kind of semiconductor device, includes an insulating layer 353, and a conductive layer 351 and a conductive layer 352 that are formed to be embedded in the insulating layer 353. The conductive layer 351 and the conductive layer 352 can be formed using the same material in the same manufacturing step. A chemical mechanical polishing (CMP) method or the like is preferably performed so that top surfaces of the insulating layer 353, the conductive layer 351, and the conductive layer 352 are level with or substantially level with one another (in the Z direction). The unevenness of a sample surface is reduced by performing CMP treatment, which increases the coverage with insulating layers and conductive layers that are to be formed later.

An insulating layer 354 is provided over the insulating layer 353, the conductive layer 351, and the conductive layer 352, and a conductive layer 355 is provided over the insulating layer 354. The conductive layer 351 has a region overlapping with the conductive layer 355 with the insulating layer 354 therebetween.

A region where the conductive layer 351, the conductive layer 355, and the insulating layer 354 are included and where the conductive layer 351 and the conductive layer 355 overlap with each other with the insulating layer 354 therebetween functions as the capacitor 235. Thus, the conductive layer 355 functions as the one electrode of the capacitor 235. The conductive layer 351 functions as the other electrode of the capacitor 235.

For the insulating layer 354 functioning as a dielectric of the capacitor 235, a material with a high relative dielectric constant (also referred to as a “high-k material”) may be used. When a high-k material is used for the insulating layer 354, the electrostatic capacitance needed for the capacitor 235 can be ensured and the insulating layer 354 can have a large thickness. The insulating layer 354 with a large thickness increases the withstand voltage between the conductive layer 351 and the conductive layer 355 to inhibit electrostatic breakdown. As a result, the reliability of the capacitor 235 is improved. Thus, the reliability of the semiconductor device including the capacitor 235 is improved.

A ferroelectric may be used for the insulating layer 354 functioning as the dielectric of the capacitor 235. The ferroelectric has a property of causing internal polarization by application of an electric field from the outside and maintaining the polarization even after the electric field is made zero. Thus, with a capacitor (also referred to as a “ferroelectric capacitor”) that includes this material as a dielectric, a nonvolatile storage element can be achieved.

The memory circuit 231 illustrated in FIG. 13A to FIG. 13C includes an insulating layer 357 over the insulating layer 354 and the conductive layer 355, an insulating layer 358 over the insulating layer 357, and an insulating layer 359 over the insulating layer 358. Note that the insulating layer 357, the insulating layer 358, and the insulating layer 359 are collectively referred to as an insulating layer 356 or a spacer layer in some cases. A conductive layer 361 is provided over the insulating layer 359.

In a region overlapping with part of the conductive layer 355, an opening 362 is provided in the conductive layer 361, the insulating layer 359, the insulating layer 358, and the insulating layer 357. The memory circuit 231 illustrated in FIG. 13A to FIG. 13C includes a semiconductor layer 363 that covers the opening 362. The semiconductor layer 363 includes a region overlapping with a bottom portion of the opening 362 and a region overlapping with a side surface of the opening 362. That is, the semiconductor layer 363 includes a region in contact with the insulating layer 356. In FIG. 13B and FIG. 13C, the semiconductor layer 363 includes a region in contact with a side surface of the insulating layer 357, a region in contact with a side surface of the insulating layer 358, and a region in contact with a side surface of the insulating layer 359.

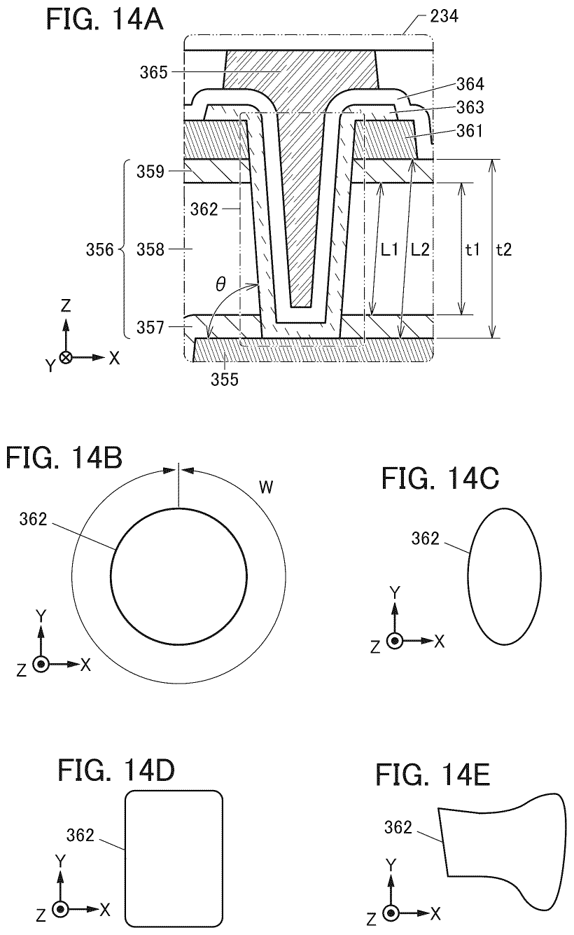

The semiconductor layer 363 includes a region in contact with the conductive layer 355 and a region in contact with the conductive layer 361. That is, part of the semiconductor layer 363 is electrically connected to the conductive layer 355, and another part of the semiconductor layer 363 is electrically connected to the conductive layer 361. The semiconductor layer 363 may include a region extending beyond an end portion of the conductive layer 361 (see FIG. 13A and FIG. 14A).

An insulating layer 364 is provided over the insulating layer 359, the conductive layer 361, and the semiconductor layer 363. A conductive layer 365 is provided over the insulating layer 364. In FIG. 13A, the conductive layer 365 extends in the Y direction.

The insulating layer 364 and the conductive layer 365 each include a region overlapping with the opening 362. In the opening 362, the insulating layer 364 includes a region overlapping with a side surface of the conductive layer 361 with the semiconductor layer 363 therebetween and a region overlapping with a side surface of the insulating layer 356 (the insulating layer 359, the insulating layer 358, and the insulating layer 357). In the opening 362, the conductive layer 365 includes a region overlapping with the side surface of the opening 362 (the side surface of the insulating layer 356) with the insulating layer 364 and the semiconductor layer 363 therebetween.

The thickness of the semiconductor layer 363 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The thickness of the insulating layer 364 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 364 may have a region with the above-described thickness.

An insulating layer 366 is provided over the insulating layer 364 (see FIG. 13B). Top surfaces of the conductive layer 365 and the insulating layer 366 are preferably level with or substantially level with each other (in the Z direction). For example, CMP treatment or the like is preferably performed so that the top surfaces of the conductive layer 365 and the insulating layer 366 can be level with or substantially level with each other. When the top surfaces of the conductive layer 365 and the insulating layer 366 are level with or substantially level with each other, the coverage with insulating layers and conductive layers to be formed later can be increased.

An insulating layer 367 is provided over the conductive layer 365 and the insulating layer 366. In a region overlapping with the conductive layer 352, a conductive layer 368 is provided so as to be embedded in parts of the insulating layer 367, the insulating layer 366, the insulating layer 364, the conductive layer 361, the insulating layer 359, the insulating layer 358, the insulating layer 357, and the insulating layer 354. The conductive layer 368 is electrically connected to the conductive layer 361 and the conductive layer 352. The conductive layer 368 and the conductive layer 352 function as a contact plug. The conductive layer 368 formed through a plurality of layers is also referred to as a “through electrode” or a “VIA”.

The conductive layer 361 functions as one of a source electrode and a drain electrode of the transistor 234. The conductive layer 355 functions as the other of the source electrode and the drain electrode of the transistor 234. For example, in the case where the conductive layer 361 functions as the drain electrode of the transistor 234, the conductive layer 355 functions as the source electrode of the transistor 234. The transistor 234 is formed in a region overlapping with the conductive layer 355. The transistor 234 has a region overlapping with the capacitor 235.

The semiconductor layer 363 functions as a semiconductor layer of the transistor 234 where a channel is formed (a semiconductor layer including a channel formation region); the insulating layer 364 functions as a gate insulating layer; and the conductive layer 365 functions as a gate electrode. In other words, the transistor 234 is provided in a region including the opening 362.

The transistor 233 is formed in a region not overlapping with the transistor 234 but overlapping with the conductive layer 355. The transistor 233 has a region overlapping with the capacitor 235. The transistor 233 has a structure similar to that of the transistor 234 and is formed concurrently with the transistor 234. Thus, the description of the transistor 233 can be made by replacing the transistor 234 in the description of the transistor 234 with the transistor 233.

In the transistor 234, the source electrode and the drain electrode are placed in the Z direction. That is, a source and a drain of the transistor 234 are placed at different levels. In other words, the source and the drain of the transistor 234 are placed at different positions in the Z direction. Such a transistor is also referred to as a “vertical-channel transistor”, a “vertical transistor”, or a “VFET (Vertical Field Effect Transistor)”.

The source electrode and the drain electrode of the vertical-channel transistor of one embodiment of the present invention are placed in the Z direction. That is, the channel formation region, the source region, and the drain region are placed in the Z direction. The area occupied by the vertical transistor can be smaller than that occupied by a conventional transistor in which the channel formation region, the source region, and the drain region are provided separately on the X-Y plane.

Thus, when the vertical-channel transistor is used in a semiconductor device, the area occupied by the semiconductor device can be reduced. In addition, when the vertical-channel transistor is used in a semiconductor device, high integration of the semiconductor device can be achieved. It is also possible to increase the storage capacity per unit area of a storage device including the semiconductor device.

The channel length of a conventional transistor is determined by the light exposure limit of photolithography. The channel length of the vertical-channel transistor of one embodiment of the present invention can be determined by the thickness of the insulating layer 356 or the insulating layer 358. Thus, the transistor 234 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 234 can have higher on-state current and improved frequency characteristics. The use of a vertical-channel transistor enables a semiconductor device with high operation speed to be provided.

### Component Materials of Semiconductor Device

Examples of materials that can be used for the semiconductor device of one embodiment of the present invention are described below.

### Substrate

In the case where the semiconductor device is provided over a substrate, there is no particular limitation on a material used for the substrate. The material is determined in accordance with the purpose in consideration of whether it has a light-transmitting property, heat resistance high enough to withstand heat treatment, or the like. For example, an insulator substrate, a semiconductor substrate, or a conductor substrate may be used. As the insulator substrate, for example, a glass substrate such as barium borosilicate glass or aluminoborosilicate glass, a ceramic substrate, a quartz substrate, a sapphire substrate, or a stabilized zirconia substrate (e.g., an yttria-stabilized zirconia substrate) can be used. Alternatively, a semiconductor substrate, a flexible substrate, a resin substrate, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. Another example is a semiconductor substrate in which an insulator region is included in the semiconductor substrate described above, e.g., an SOI (Silicon On Insulator) substrate. The semiconductor substrate may be a single crystal semiconductor or a polycrystalline semiconductor.

Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator.

As the materials of the flexible substrate and the resin substrate, for example, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide imide, polyurethane, polyvinyl chloride, polyvinylidene chloride, polypropylene, polytetrafluoroethylene (PTFE), an ABS resin, cellulose nanofiber, or the like can be used.

When the above-described material is used for the substrate, a lightweight semiconductor device including the transistor 234 can be provided. Furthermore, when the above-described material is used for the substrate, a shock-resistant semiconductor device can be provided. Moreover, when the above-described material is used for the substrate, a semiconductor device that is less likely to be broken can be provided.

Alternatively, these substrates provided with elements may be used. Examples of the element provided for the substrate include a capacitor, a resistor, a switching element, a light-emitting element, and a storage element.

### Insulating Layer

As the insulating layer, an insulating oxide, an insulating nitride, an insulating oxynitride, an insulating nitride oxide, an insulating metal oxide, an insulating metal oxynitride, an insulating metal nitride oxide, or the like can be used. For example, a single layer or a stacked layer of an insulating material selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used for the insulating layer. A material in which two or more materials selected from an oxide material, a nitride material, an oxynitride material, and a nitride oxide material are mixed may be used.

Note that in this specification and the like, a nitride oxide refers to a material that contains more nitrogen than oxygen. An oxynitride refers to a material that contains more oxygen than nitrogen. The content of each element can be measured by Rutherford backscattering spectrometry (RBS), for example.

As miniaturization and high integration of transistors progress, a problem such as leakage current may arise because of a thinner gate insulating layer. When a high-k material (a high dielectric constant material or a material with a high relative dielectric constant) is used for an insulating layer functioning as the gate insulating layer, a gate potential during operation of the transistor can be reduced while the physical thickness is maintained. A substance with a high dielectric constant, such as lead zirconate titanate (PZT), strontium titanate (SrTiO₃), or (Ba,Sr)TiO₃ (BST), can be used for the insulating layer in some cases. By contrast, when a material with a low relative dielectric constant is used for the insulating layer functioning as an interlayer film, parasitic capacitance generated between wirings can be reduced. Thus, a material is preferably selected depending on the function needed for the insulating layer.

Examples of materials with a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of materials with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

There is no particular limitation on the formation method of the insulating material, and a variety of formation methods such as an evaporation method, an ALD (atomic layer deposition) method, a CVD (chemical vapor deposition) method, a sputtering method, and a spin coating method can be employed.

For example, it is preferable that the insulating layer 353 and the insulating layer 367 be formed using an insulating material through which impurities are less likely to pass. For example, a single layer or a stacked layers of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of insulating materials through which impurities are less likely to pass, include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities do not easily pass is used for the insulating layer 353, impurity diffusion from below the insulating layer 353 can be inhibited, and the reliability of the transistor 234 can be improved. That is, the reliability of a semiconductor device including the transistor 234 can be improved. When the insulating material through which impurities are less likely to pass is used for the insulating layer 367, impurity diffusion from above the insulating layer 367 can be inhibited, and the reliability of the transistor 234 can be improved. That is, the reliability of a semiconductor device including the transistor 234 can be improved.

As the insulating layer, an insulating layer capable of functioning as a planarization layer may be used. Examples of materials capable of functioning as the planarization layer include an acrylic resin, polyimide, an epoxy resin, polyamide, polyimide amide, a siloxane resin, a benzocyclobutene resin, a phenol resin, and precursors of these resins. Besides the above organic materials, a low-k material (a low dielectric constant material or a material with a low relative dielectric constant), a siloxane resin, PSG (phosphosilicate glass), BPSG (borophosphosilicate glass), or the like can also be used. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. In addition, the organic group may include a fluoro group.

As the insulating layer 354 functioning as the dielectric of the capacitor 235, a three-layer insulating layer (also referred to as “ZAZ”) including aluminum oxide sandwiched between two zirconium oxide layers may be used. ZAZ is a material with a high relative dielectric constant, and when ZAZ is used as the dielectric of the capacitor 235, the area occupied by the capacitor 235 can be reduced.

As described above, a material that can have ferroelectricity is preferably used for the insulating layer 354 so that the capacitor 235 function as a ferroelectric capacitor.

As the material that can have ferroelectricity, for example, hafnium oxide is preferably used. Alternatively, as the material that can have ferroelectricity, a metal oxide such as zirconium oxide or HfZrO_{X} (hereinafter also referred to as “HfZrOx”, Xis a real number greater than 0) may be used. Alternatively, as the material that can have ferroelectricity, a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide may be used.

Here, the atomic ratio of a hafnium atom to the element J1 can be set as appropriate. For example, the atomic ratio of a hafnium atom to a zirconium atom may be 1:1 or in the vicinity thereof. Alternatively, as the material that can have ferroelectricity, a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide, or the like can be used. The atomic ratio of a zirconium atom to the element J2 can be set as appropriate; the atomic ratio of a zirconium atom to the element J2 is, for example, 1:1 or in the vicinity thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

As the material that can have ferroelectricity, scandium aluminum nitride (Al₁₋ₐScₐN_{b} (a is a real number greater than 0 and less than 0.5, and b is 1 or an approximate value thereof), hereinafter simply referred to as AlScN), Al—Ga—Sc nitride, Ga—Sc nitride, or the like can be used.

### Conductive Layer

As a conductive material that can be used for conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like; an alloy containing the above metal element as a component; an alloy containing the above metal elements in combination; or the like can be used.

For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. A semiconductor having high electrical conductivity, typified by polycrystalline silicon containing an impurity element such as phosphorus, or silicide such as nickel silicide may be used. There is no particular limitation on the formation method of the conductive material, and a variety of formation methods such as an evaporation method, an ALD method, a CVD method, a sputtering method, and a spin coating method can be employed.

A Cu—X alloy (X is Mn, Ni, Cr, Fe, Co, Mo, Ta, or Ti) may be used as the conductive material. A layer formed using a Cu—X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, can be used. A conductive material containing nitrogen, such as titanium nitride, tantalum nitride, or tungsten nitride, can also be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer including silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above conductive materials may be stacked and used. For example, the conductive layer may have a stacked-layer structure in which a material containing the above-described metal element is combined with a conductive material containing oxygen. It is also possible to employ a stacked-layer structure in which a material containing the above-described metal element is combined with a conductive material containing nitrogen. It is also possible to employ a stacked-layer structure in which a material containing the above-described metal element is combined with a conductive material containing oxygen and a conductive material containing nitrogen.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

In the case where the capacitor 235 functions as a ferroelectric capacitor, a material that easily causes polarization in the insulating layer 354 is preferably used for the conductive layer 351 and the conductive layer 355, which are in contact with the insulating layer 354 that is a ferroelectric. For example, titanium nitride is preferably used for the conductive layer 351 and the conductive layer 355.

### Semiconductor Layer

For the semiconductor layer 363, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, or a nitride semiconductor may be used. As the compound semiconductor, an organic substance having semiconductor characteristics or a metal oxide having semiconductor characteristics (also referred to as an oxide semiconductor) can be used. These semiconductor materials may contain an impurity as a dopant.

For the semiconductor layer 363, single crystal silicon, polycrystalline silicon, microcrystalline silicon, and amorphous silicon may be used, for example. As the polycrystalline silicon, for example, low-temperature polysilicon (LTPS) may be used.

The transistor including amorphous silicon in the semiconductor layer 363 can be formed over a large glass substrate, and can be manufactured at low cost. The transistor including polycrystalline silicon in the semiconductor layer 363 has high field-effect mobility and enables high-speed operation. The transistor including microcrystalline silicon in the semiconductor layer 363 has higher field-effect mobility and enables higher speed operation than the transistor including amorphous silicon.

The semiconductor layer 363 may include a layered material functioning as a semiconductor. The layered material generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

An oxide semiconductor has a band gap of 2 eV or more; thus, a transistor using an oxide semiconductor, which is a kind of metal oxide, used for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has small change in characteristics. For example, the off-state current hardly increases even in the high-temperature environment. Specifically, the off-state current hardly increases even at an environmental temperature higher than or equal to room temperature and lower than or equal to 200 °C. Furthermore, the on-state current of the OS transistor is unlikely to decrease even in a high-temperature environment. Therefore, the semiconductor device including the OS transistor can operate stably and have high reliability even in a high-temperature environment.

Note that OS transistors are preferably used as the transistor 233 and the transistor 234 in this embodiment and the like. Since an OS transistor has a high breakdown voltage between the source and the drain, the channel length can be shortened. Thus, the on-state current can be increased. The OS transistor is suitably used as a vertical-channel transistor.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three kinds selected from indium, an element M, and zinc. The element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. Note that in this specification and the like, a metal element and a metalloid element may be collectively referred to as a “metal element”, and a “metal element” in this specification and the like may include a metalloid element.

For example, it is possible to use indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as “GZO”), aluminum zinc oxide (Al—Zn oxide, also referred to as “AZO”), indium aluminum zinc oxide (In—Al—Zn oxide, also referred to as “IAZO”), indium tin zinc oxide (In—Sn—Zn oxide), indium titanium zinc oxide (In—Ti—Zn oxide), indium gallium zinc oxide (In—Ga—Zn oxide, also referred to as “IGZO”), indium gallium tin zinc oxide (In—Ga—Sn—Zn oxide, also referred to as “IGZTO”), or indium gallium aluminum zinc oxide (In—Ga—Al—Zn oxide, also referred to as “IGAZO” or “IAGZO”). Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, a transistor containing a metal element with a large period number in the periodic table can have high field-effect mobility in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of metal elements in the main elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of metal elements in the main elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor vary depending on the composition of the metal oxide used for the semiconductor layer. Therefore, by changing the composition of the metal oxide in accordance with the electrical characteristics and reliability required for the transistor, the semiconductor device can have both excellent electrical characteristics and high reliability.

In the case where In—Zn oxide is used for the semiconductor layer of the OS transistor, a metal oxide in which the atomic ratio of indium is higher than or equal to the atomic ratio of zinc may be used. For example, a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the vicinity thereof may be used.

In the case where In—Sn oxide is used for the semiconductor layer of the OS transistor, a metal oxide in which the atomic ratio of indium is higher than or equal to the atomic ratio of tin may be used. For example, a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the vicinity thereof may be used.

In the case where In—Sn—Zn oxide is used for the semiconductor layer of the OS transistor, a metal oxide in which the atomic ratio of indium is higher than the atomic ratio of tin may be used. It is further preferable to use a metal oxide in which the atomic ratio of zinc is higher than the atomic ratio of tin. For example, a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the vicinity thereof may be used.

In the case where In—Al—Zn oxide is used for the semiconductor layer of the OS transistor, a metal oxide in which the atomic ratio of indium is higher than the atomic ratio of aluminum may be used. It is further preferable to use a metal oxide in which the atomic ratio of zinc is higher than the atomic ratio of aluminum. For example, a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn =10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the vicinity thereof may be used.

In the case of using In—Ga—Zn oxide for the semiconductor layer of the OS transistor, a metal oxide in which the proportion of the number of indium atoms in the number of atoms of the metal elements is higher than the proportion of the number of gallium atoms may be used. It is further preferable to use a metal oxide in which the atomic ratio of zinc is higher than the atomic ratio of gallium. For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the vicinity thereof may be used in the semiconductor layer.

In the case of using In—M—Zn oxide for the semiconductor layer of the OS transistor, a metal oxide in which the proportion of the number of indium atoms in the number of atoms of the metal elements is higher than the proportion of the number of element M atoms may be used. It is further preferable to use a metal oxide in which the atomic ratio of zinc is higher than the atomic ratio of the element M. For example, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or in the vicinity thereof may be used in the semiconductor layer.

In the case where In—M—Zn oxide is used for the semiconductor layer, a metal oxide in which the atomic ratio of metal elements is In:M:Zn=1:3:2 [atomic ratio] or in the vicinity thereof, In:M:Zn=1:3:4 [atomic ratio] or in the vicinity thereof, In:M:Zn=1:1:0.5 [atomic ratio] or in the vicinity thereof, In:M:Zn=1:1:1 [atomic ratio] or in the vicinity thereof, In:M:Zn=1:1:1.2 [atomic ratio] or in the vicinity thereof, In:M:Zn=1:1:2 [atomic ratio] or in the vicinity thereof, or In:M:Zn=4:2:3 [atomic ratio] or in the vicinity thereof may be used. Note that a composition in the vicinity includes the range of ±30% of an intended atomic ratio. Gallium is preferably used as the element M.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio of indium, the element M, and zinc is preferably within the ranges given above.

It is preferable to use a metal oxide in which the proportion of the number of indium atoms in the total number of atoms of metal elements in the main elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case where In—M—Zn oxide is used for the semiconductor layer, the proportion of the number of indium atoms in the sum of the numbers of atoms of indium, the element M, and zinc is preferably within the ranges given above.

As described above, by increasing the proportion of the number of indium atoms in the total number of atoms of metal elements in the main elements contained in the metal oxide, the field-effect mobility of the transistor can be increased. With the use of such a transistor, a circuit capable of high-speed operation can be manufactured. Furthermore, the area occupied by the circuit can be reduced.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an ALD method can be suitably used for forming the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately higher than or equal to 40% and lower than or equal to 90% of the atomic ratio of zinc contained in the target.

Note that when a film of the metal oxide is formed by a sputtering method, the above atomic ratio is not limited to the atomic ratio of the formed metal oxide and may be the atomic ratio of a sputtering target used for forming the film of the metal oxide.

When a film of the metal oxide is formed by an ALD method, an atomic layer is deposited one by one; therefore, effects such as formation of a film of the metal oxide having few defects such as pinholes, formation of a film of the metal oxide having high coverage, and formation of a film of the metal oxide at low temperatures are obtained. After the formation of the film of the metal oxide, impurity removal treatment is preferably performed to remove an impurity (which is typically water, hydrogen, carbon, or nitrogen here) from the metal oxide film. Examples of the impurity removal treatment include plasma treatment, microwave treatment, and heat treatment.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where light irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state; thus, the amount of change in threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, at the interface between a metal oxide containing a large amount of gallium and the gate insulating layer, gallium is bonded to excess oxygen in the gate insulating layer, which probably generates trap sites of carriers (here, electrons) easily. This might cause the change in the threshold voltage when a positive potential is supplied to a gate and carriers are trapped at the interface between the semiconductor layer and the gate insulating layer.

More specifically, in the case where In—Ga—Zn oxide is used for the semiconductor layer, a metal oxide in which the atomic ratio of indium is higher than the atomic ratio of gallium can be used for the semiconductor layer. It is further preferable to use a metal oxide in which the atomic ratio of zinc is higher than the atomic ratio of gallium. In other words, a metal oxide in which the atomic ratio of metal elements satisfy In>Ga and Zn>Ga is preferably used for the semiconductor layer.

For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn =5:1:6, In:Ga:Zn=5:1:7, In:Ga:Zn=5:1:8, In:Ga:Zn=6:1:6, In:Ga:Zn=10:1:3, In:Ga:Zn =10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the vicinity thereof may be used in the semiconductor layer of the OS transistor.

The semiconductor layer of the OS transistor is preferably formed using a metal oxide having the following compositions: the proportion of the number of gallium atoms in the number of atoms of the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that oxygen vacancy (Vo) is less likely to be generated in the metal oxide when the metal oxide contains gallium.

A metal oxide not containing gallium may be used for the semiconductor layer of the OS transistor. For example, In-Zn oxide can be used for the semiconductor layer. In this case, when the ratio of the number of indium atoms in the number of atoms of the metal elements contained in the metal oxide is increased, the field-effect mobility of the transistor can be increased. By contrast, when the ratio of the number of zinc atoms in the number of atoms of the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide where the atomic ratio of metal elements is In:Zn =2:3, In:Zn=4:1, or the neighborhood thereof can be used.

Although the case of using gallium is described as a typical example, the same applies to the case where the element M is used instead of gallium. A metal oxide in which the atomic ratio of indium is higher than the atomic ratio of the element M is preferably used for the semiconductor layer. Furthermore, a metal oxide in which the atomic ratio of zinc is higher than the atomic ratio of the element M is preferably used.

The use of a metal oxide having a low content percentage of the element M for the semiconductor layer achieves the transistor that is highly reliable against positive bias application. With use of the transistor as a transistor that is required to have high reliability against positive bias application, a highly reliable semiconductor device can be achieved.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having a composition of In:M:Zn=1:3:4 [atomic ratio] or in the vicinity thereof and a second metal oxide layer having a composition of In:M:Zn=1:1:1 [atomic ratio] or in the vicinity thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or in the vicinity thereof and a second metal oxide layer having a composition of In:Zn=4:1 [atomic ratio] or in the vicinity thereof and being provided over the first metal oxide layer may be used.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which achieves the highly reliable display device.

The higher the crystallinity of the metal oxide layer used as the semiconductor layer is, the lower the density of defect states in the semiconductor layer can be. By contrast, the use of a metal oxide layer having low crystallinity achieves a transistor through which a large amount of current can flow.

In the case where a metal oxide layer is formed by a sputtering method, the metal oxide layer with higher crystallinity can be formed as the substrate temperature (the stage temperature) in formation is increased. The metal oxide layer with higher crystallinity can be formed as the proportion of a flow rate of an oxygen gas to the whole gas (also referred to as oxygen flow rate ratio) used in film formation is increased.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer may have different compositions.

In the case where an oxide semiconductor is used for the semiconductor layer 363, a material containing hydrogen is preferably used for the insulating layer 357 and the insulating layer 359. When the insulating layer containing hydrogen is in contact with the oxide semiconductor, the oxide semiconductor in a region in contact with the insulating layer becomes an n-type semiconductor and can function as a source region or a drain region. For example, a material containing silicon, nitrogen, and hydrogen may be used for the insulating layer. Specifically, silicon nitride containing hydrogen or silicon nitride oxide containing hydrogen may be used.

The thickness of each of the insulating layer 357 and the insulating layer 359 is preferably greater than or equal to 1 nm and less than or equal to 15 nm, further preferably greater than or equal to 2 nm and less than or equal to 10 nm, still further preferably greater than or equal to 3 nm and less than or equal to 7 nm, and yet still further preferably greater than or equal to 3 nm and less than or equal to 5 nm. In the case where an oxide semiconductor is used for the semiconductor layer 363, the region of the semiconductor layer 363 that is in contact with the insulating layer 357 containing hydrogen and the region of the semiconductor layer 363 that is in contact with the insulating layer 359 containing hydrogen function as a source region and a drain region. The sizes of the source region and the drain region formed in the semiconductor layer 363 can be controlled by adjusting the thicknesses of the insulating layer 357 and the insulating layer 359.

The thickness of the insulating layer 358 is preferably greater than or equal to 1 nm and less than or equal to 50 nm, further preferably greater than or equal to 2 nm and less than or equal to 30 nm, still further preferably greater than or equal to 3 nm and less than or equal to 20 nm. The size of a channel formation region of the semiconductor layer 363 can be controlled by adjusting the thickness of the insulating layer 358.

The thicknesses of the insulating layer 357, the insulating layer 358, and the insulating layer 359 may be set as appropriate in accordance with the characteristics required for the transistor 234.

The insulating layer 357, the insulating layer 358, and the insulating layer 359 are preferably formed successively without exposure to the atmospheric environment. When the insulating layer 357, the insulating layer 358, and the insulating layer 359 are successively formed without exposure to the atmospheric environment, impurities or moisture in the atmospheric environment can be prevented from being attached to the interface between the insulating layer 357 and the insulating layer 358 and the vicinity thereof and the interface between the insulating layer 358 and the insulating layer 359 and the vicinity thereof.

In the case where an oxide semiconductor is used for the semiconductor layer 363, a conductive material that makes the oxide semiconductor an n-type semiconductor is preferably used for the conductive layer 355 in contact with the semiconductor layer 363 and the conductive layer 361 in contact with the semiconductor layer 363. For example, a conductive material containing nitrogen may be used. For example, a conductive material containing nitrogen and titanium or tantalum may be used. Another conductive material may be provided so as to overlap with the conductive material containing nitrogen.

Meanwhile, for the insulating layer 358, a material which includes oxygen and a reduced amount of hydrogen is preferably used. For example, a material containing silicon and oxygen may be used. Specifically, silicon oxide, silicon oxynitride, or the like may be used. Since hydrogen is an impurity element in an oxide semiconductor, when the semiconductor layer 363, which is an oxide semiconductor, and the insulating layer 358, which includes a reduced amount of hydrogen, are in contact with each other, the semiconductor layer 363 is less likely to become an n-type layer. Furthermore, when the semiconductor layer 363, which is an oxide semiconductor, and the insulating layer 358 containing oxygen are in contact with each other, oxygen vacancies in the semiconductor layer 363 are reduced and the transistor 234 has stable characteristics and improved reliability.

When an oxide semiconductor is used for the semiconductor layer 363, the insulating layer 358 preferably includes excess oxygen. In this specification and the like, excess oxygen refers to oxygen that is released by heating. In the case where a material containing excess oxygen is used for the insulating layer 358, a material through which oxygen is less likely to pass is preferably used for the insulating layer 357 and the insulating layer 359. Examples of the material through which oxygen is less likely to pass include a nitride of silicon and an oxide containing one or both of aluminum and hafnium. When the material through which oxygen is less likely to pass is used for the insulating layer 357 and the insulating layer 359, excess oxygen included in the insulating layer 358 is less likely to be released to a lower layer or an upper layer. Thus, a sufficient amount of oxygen can be supplied to the oxide semiconductor. For example, it is possible to use a structure in which an insulating layer containing silicon and oxygen (the insulating layer 358) is provided between two insulating layers containing silicon and nitrogen (the insulating layer 357 and the insulating layer 359).

When an oxide semiconductor is used for the semiconductor layer 363 and a material containing hydrogen is used for the insulating layer 357 and the insulating layer 359, the region of the semiconductor layer 363 that is in contact with the insulating layer 357 and the region of the semiconductor layer 363 that is in contact with the insulating layer 359 are supplied with hydrogen and become n-type regions. Thus, the region of the semiconductor layer 363 that is in contact with the conductive layer 361 and the region of the semiconductor layer 363 that is in contact with the insulating layer 359 function as one of the source (a source region) and the drain (a drain region). The region of the semiconductor layer 363 that is in contact with the conductive layer 355 and the region of the semiconductor layer 363 that is in contact with the insulating layer 357 function as the other of the source (the source region) and the drain (the drain region).

FIG. 14A is an enlarged view of a cross section of the transistor 234 illustrated in FIG. 13B. In the transistor 234, which is a VFET having the above structure, the length of the side surface of the insulating layer 358 seen from the X direction or the Y direction corresponds to a channel length L (channel length L1) (see FIG. 14A). Hence, the channel length L of the transistor 234 is determined in accordance with a thickness t1 of the insulating layer 358.

A material that includes no hydrogen or an extremely small amount of hydrogen may be used for the insulating layer 357 and the insulating layer 359. For example, silicon nitride that includes an extremely small amount of hydrogen or silicon nitride oxide that includes an extremely small amount of hydrogen may be used. In that case, the region of the semiconductor layer 363 that is in contact with the insulating layer 357 and the region of the semiconductor layer 363 that is in contact with the insulating layer 359 are not become n-type regions. Thus, the region of the semiconductor layer 363 that is in contact with the conductive layer 361 functions as the one of the source (the source region) and the drain (the drain region). The region of the semiconductor layer 363 that is in contact with the conductive layer 355 functions as the other of the source (the source region) and the drain (the drain region). The region of the semiconductor layer 363 that is in contact with the insulating layer 358 functions as the channel formation region.

In that case, the channel length L (channel length L2) is the sum of the lengths of side surfaces of the insulating layer 357, the insulating layer 358, and the insulating layer 359 seen from the X direction or the Y direction. Hence, the channel length L of the transistor 234 is determined in accordance with a thickness t2, which is the sum of the thicknesses of the insulating layer 357, the insulating layer 358, and the insulating layer 359.

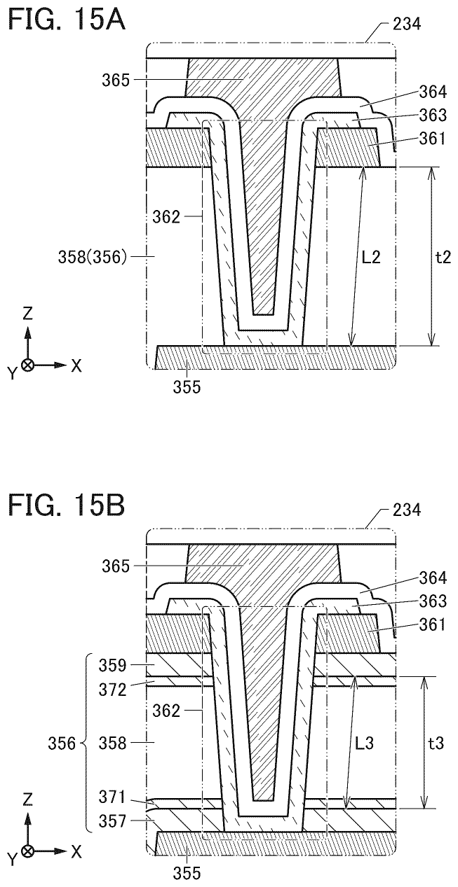

FIG. 15A and FIG. 15B illustrate modification examples of FIG. 14A. For example, it is also possible to use a structure in which the insulating layer 357 and the insulating layer 359 are not provided and only the insulating layer 358 is provided to be in contact with the conductive layer 355 and the conductive layer 361 (see FIG. 15A). In that case, the length of the side surface of the insulating layer 358 seen from the X direction or the Y direction is the channel length L. Hence, the channel length L of the transistor 234 is determined in accordance with a thickness t of the insulating layer 358. In the case of the structure illustrated in FIG. 15A, the insulating layer 358 is referred to as the insulating layer 356 in some cases. Note that the channel length L illustrated in FIG. 15A can be rephrased as the channel length L2 illustrated in FIG. 14A, and the thickness t2 illustrated in FIG. 15A can be rephrased as the thickness t2 illustrated in FIG. 14A.

When an oxide semiconductor is used for the semiconductor layer 363, a material containing hydrogen is used for the insulating layer 357 and the insulating layer 359, and a material containing excess oxygen is used for the insulating layer 358, hydrogen contained in the insulating layer 357 and the insulating layer 359 is bonded to excess oxygen contained in the insulating layer 358, whereby the region of the semiconductor layer 363 that is in contact with the insulating layer 357 and the region of the semiconductor layer 363 that is in contact with the insulating layer 359 are not supplied with a sufficient amount of hydrogen and are less likely to become n-type regions. Likewise, the region of the semiconductor layer 363 that is in contact with the insulating layer 358 is not supplied with a sufficient amount of oxygen.

In order to solve such a problem, an insulating layer 371 through which oxygen and nitrogen are less likely to pass may be provided between the insulating layer 357 and the insulating layer 358, and an insulating layer 372 through which oxygen and nitrogen are less likely to pass may be provided between the insulating layer 359 and the insulating layer 358 (see FIG. 15B). A material through which oxygen and nitrogen are less likely to pass can be achieved by using, for example, a nitride of silicon. Note that in the case of the structure illustrated in FIG. 15B, the insulating layer 357, the insulating layer 371, the insulating layer 358, the insulating layer 372, and the insulating layer 359 are collectively referred to as the insulating layer 356 in some cases.

When the material through which oxygen is less likely to pass is used for the insulating layer 371 and the insulating layer 372, bonding of hydrogen contained in the insulating layer 357 and the insulating layer 359 to excess oxygen included in the insulating layer 358 is hindered. Accordingly, a sufficient amount of hydrogen is supplied to the region of the semiconductor layer 363 that is in contact with the insulating layer 357 and the region of the semiconductor layer 363 that is in contact with the insulating layer 359. Likewise, a sufficient amount of oxygen is supplied to the region of the semiconductor layer 363 that is in contact with the insulating layer 358.

In that case, a channel length L3 is the sum of the lengths of side surfaces of the insulating layer 371, the insulating layer 358, and the insulating layer 372 seen from the X direction or the Y direction. Hence, the channel length L of the transistor 234 is determined in accordance with a thickness t3, which is the sum of the thicknesses of the insulating layer 371, the insulating layer 358, and the insulating layer 372.

The channel length L of the transistor 234 of one embodiment of the present invention is determined in accordance with the thickness of the insulating layer provided between the conductive layer 361 and the conductive layer 355. As a result, the transistor with a short channel length L can be formed with high accuracy. Furthermore, variations in characteristics among a plurality of the transistors 234 are also reduced. Accordingly, operation of the semiconductor device including the transistor 234 can be stabilized and reliability thereof can be improved. The reduced variations in characteristics increases the circuit design flexibility of the semiconductor device, thereby reducing the operation voltage. Thus, the power consumption of the semiconductor device can be reduced.

This embodiment describes a structure in which three insulating layers (the insulating layer 357, the insulating layer 358, and the insulating layer 359) or five insulating layers (the insulating layer 357, the insulating layer 358, the insulating layer 359, the insulating layer 371, and the insulating layer 372) are included between the conductive layer 355 and the conductive layer 361; however, the number of insulating layers between the conductive layer 355 and the conductive layer 361 is not limited thereto. The number of insulating layers between the conductive layer 355 and the conductive layer 361 may be one, two, four, or six or more.

In order to improve the coverage with the semiconductor layer 363, the insulating layer 364, and the conductive layer 365 formed in the opening 362, a taper angle θ of the side surface of the opening 362, i.e., the taper angle θ of each side surface of the insulating layer 357, the insulating layer 358, and the insulating layer 359 is greater than or equal to 45° and less than or equal to 90°, preferably greater than or equal to 50° and less than or equal to 75°. Note that the taper angle θ of the side surface of the layer (the insulating layer, the conductive layer, or the semiconductor layer) refers to the angle formed between the bottom surface and the side surface of the layer (see FIG. 14A).

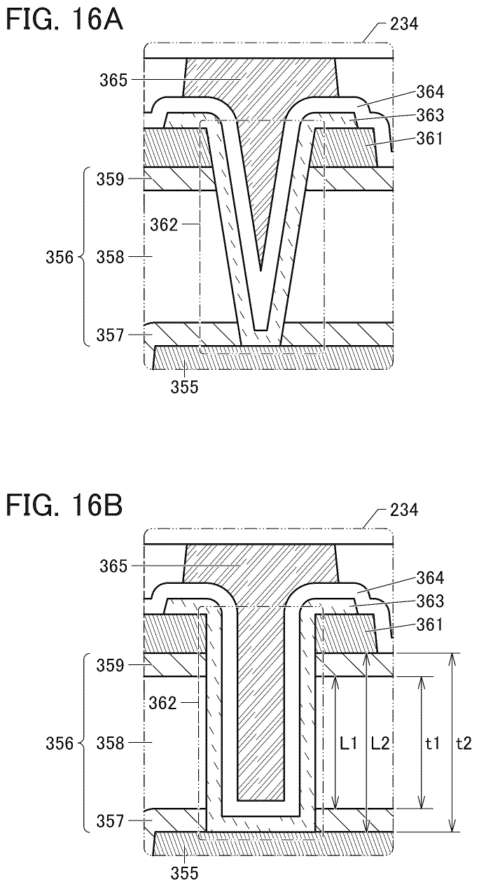

FIG. 16A and FIG. 16B illustrate variation examples of FIG. 14A. When the area of the bottom portion of the opening 362 is reduced as illustrated in FIG. 16A, the taper angle θ of the side surface of the opening 362 can be increased without an increase in the area occupied by the transistor 234. A larger taper angle θ of the side surface of the opening 362 can increase the coverage with the semiconductor layer 363, the insulating layer 364, and the conductive layer 365.

When the area of the bottom portion of the opening 362 is reduced, the conductive layer 365 is sometimes tapered off in the opening 362 toward the bottom portion of the opening 362. Such a shape of the conductive layer 365 is sometimes referred to as a “needle-like” or “pyramidal” shape.

As illustrated in FIG. 16B, the opening 362 may have a perpendicular or substantially perpendicular side surface as long as the coverage with the semiconductor layer 363, the insulating layer 364, and the conductive layer 365 is ensured. That is, the taper angle θ of the side surface of the opening 362 may be 90° or approximately 90°. The perpendicular or substantially perpendicular side surface of the opening 362 can reduce the area occupied by the transistor 234. Thus, the area occupied by the semiconductor device including the transistor 234 can be reduced.

When the opening 362 has the perpendicular side surface, the channel length L1 and the thickness t1 of the insulating layer 358 are equal to each other. When the opening 362 has the perpendicular side surface, the channel length L2 and the thickness t2 of the insulating layer 356 are equal to each other.

Since the semiconductor layer 363 is provided in the opening 362, the length of the circumference of the opening 362 seen from the Z direction is a channel width W of the transistor 234 (see FIG. 14B). The length of the circumference is determined, for example, at the position of half of the thickness t1 of the insulating layer 358 or at the position of half of the thickness ts of the insulating layer 358. Note that the length of the circumference of the opening 362 at an arbitrary position may be regarded as the channel width W as necessary. For example, the length of the circumference at the lowest portion of the opening 362 may be regarded as the channel width W, or the length of the circumference at the uppermost portion of the opening 362 may be regarded as the channel width W.

In the storage device of one embodiment of the present invention, the channel length L is preferably shorter than at least the channel width W. In one embodiment of the present invention, the channel length L is greater than or equal to 0.1 times and less than or equal to 0.99 times, preferably greater than or equal to 0.5 times and less than or equal to 0.8 times the channel width W.

Although the outline (the planar shape) of the opening 362 seen from the Z direction is circular in FIG. 14B, the outline is not limited to this. For example, the outline of the opening 362 seen from the Z direction may be elliptical (see FIG. 14C) or rectangular (see FIG. 14D). Note that FIG. 14D shows a rectangular shape having rounded corner portions. For another example, the outline of the opening 362 seen from the Z direction may have a shape including one or both of a straight portion and a curved portion (see FIG. 14E).

Note that the opening 362 preferably has a minute size. For example, the maximum width of the opening 362 (the maximum diameter in the case where the opening 362 is circular) seen from the Z direction is preferably less than or equal to 60 nm, further preferably less than or equal to 50 nm, still further preferably less than or equal to 40 nm, and yet still further preferably less than or equal to 30 nm. The maximum width of the opening 362 seen from the Z direction may be less than or equal to 20 nm. Note that the minimum width of the opening 362 (the minimum diameter in the case where the opening 362 is circular) seen from the Z direction is preferably greater than or equal to 1 nm, further preferably greater than or equal to 5 nm. Such a minute opening 362 is preferably formed by a lithography method using an electron beam or short-wavelength light such as EUV light.

In the transistor 234 of one embodiment of the present invention, the capacitance value of parasitic capacitance generated between the gate and the source and the capacitance value of parasitic capacitance generated between the gate and the drain are different from each other. Specifically, in a capacitor C1 generated between the conductive layer 365 and the conductive layer 361 and a capacitor C2 generated between the conductive layer 365 and the conductive layer 355, the capacitance value of the capacitor C1 is higher than the capacitance value of the capacitor C2.

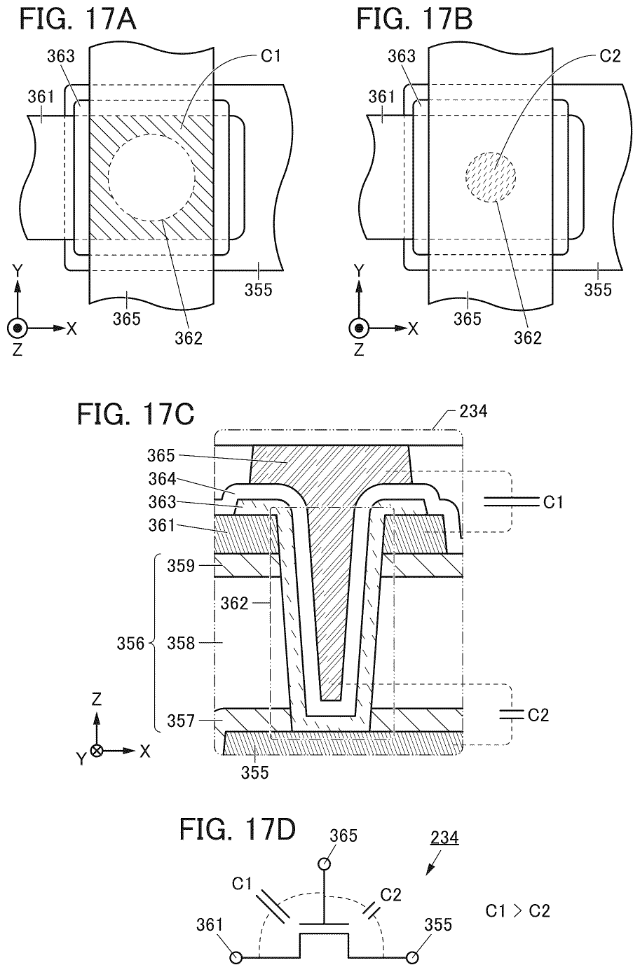

FIG. 17A and FIG. 17B are plan views of the transistor 234, and FIG. 17C is a cross-sectional view of the transistor 234. Note that some components are not illustrated in FIG. 17A and FIG. 17B. FIG. 17D is an equivalent circuit diagram of the transistor 234.

When the transistor 234 of one embodiment of the present invention is seen from the Z direction, the conductive layer 365 overlaps with the conductive layer 361 at the periphery of the opening 362 and overlaps with the conductive layer 355 at the bottom portion of the opening 362. In FIG. 17A, a region functioning as the capacitor C1 when seen from the Z direction is hatched. A region where the conductive layer 365 and the conductive layer 361 overlap with each other with the semiconductor layer 363 and the insulating layer 364 therebetween functions as the capacitor C1.

In FIG. 17B, a region functioning as the capacitor C2 when seen from the Z direction is hatched. A region where the conductive layer 365 and the conductive layer 355 overlap with each other with the semiconductor layer 363 and the insulating layer 364 therebetween in the bottom portion of the opening 362 functions as the capacitor C2.

According to FIG. 17A and FIG. 17B, the region functioning as the capacitor C1 has a larger area than the region functioning as the capacitor C2. When the area of the region functioning as the capacitor C1 is larger than the area of the region functioning as the capacitor C2, the capacitance value of the capacitor C1 is larger than that of the capacitor C2.

By utilizing this, the capacitor C1 and the capacitor C2, which are parasitic capacitances, can function as capacitors intentionally. When the area where the conductive layer 365 and the conductive layer 355 overlap with each other is changed in order to change the capacitance value of the capacitor C2, the shape of the opening 362 is changed; that is, the length of the circumference of the opening 362 is changed. The length of the circumference of the opening 362 is the channel width W of the transistor 234. Since the change in a length p of the circumference directly influences a change in the electrical characteristics of the transistor 234, the capacitance value of the capacitor C2 is difficult to control.

In contrast, the area where the conductive layer 365 and the conductive layer 361 overlap with each other is easy to control and less likely to influence the electrical characteristics of the transistor 234. For example, by increasing the area where the conductive layer 365 and the conductive layer 361 overlap with each other, the capacitance value of the capacitor C1 can be increased.

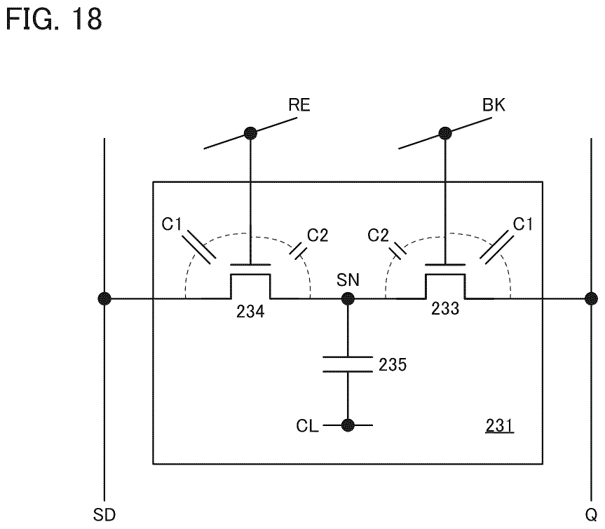

FIG. 18 is a circuit diagram of the memory circuit 231. In the case where VFETs are used as the transistor 233 and the transistor 234 included in the memory circuit 231, the capacitor C2 is preferably formed between the gate of the transistor and the capacitor 235. In the transistor 233, the capacitor C1 is preferably formed between the gate and the terminal Q. In the transistor 234, the capacitor C1 is preferably formed between the gate and the terminal SD.

When the capacitance value between the gate of the transistor 233 and the capacitor 235 is high, the node SN is likely to be affected by a potential change of the signal BK. When the capacitance value between the gate of the transistor 234 and the capacitor 235 is large, the node SN is likely to be affected by a potential change of the signal RE. In order to inhibit the potential change of the node SN and make the memory circuit 231 operate more stably, the capacitor C2 of each of the transistor 233 and the transistor 234 is preferably formed between the node SD and the gate.

That is, in the transistor 233, the conductive layer 361 is preferably electrically connected to the terminal Q, and the conductive layer 355 is preferably electrically connected to one electrode (the node SN) of the capacitor 235. In the transistor 234, the conductive layer 361 is preferably electrically connected to the terminal SD, and the conductive layer 355 is preferably electrically connected to one electrode (the node SN) of the capacitor 235.

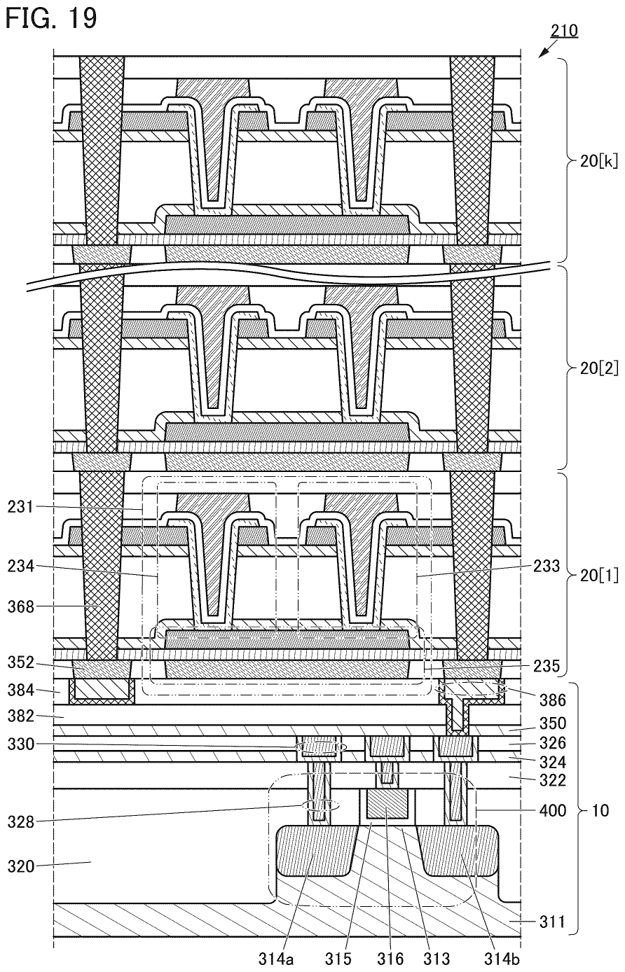

FIG. 19 illustrates a stacked-layer structure example of the OSFF 210, which is a kind of semiconductor device. The OSFF 210 illustrated in FIG. 19 includes the k layers 20 each including the memory circuit 231 above the layer 10 including the scan flip-flop 220. In FIG. 19, the structure illustrated in FIG. 13 is exemplified as the memory circuit 231 included in each of the k layers 20. In order to reduce repeated description, the description of the memory circuit 231 is omitted here.

FIG. 19 illustrates an example of a transistor 400 included in the scan flip-flop 220. The transistor 400 is provided on a substrate 311 and includes a conductive layer 316 functioning as a gate, an insulating layer 315 functioning as a gate insulator, a semiconductor region 313 formed of part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

In the transistor 400 illustrated in FIG. 19, the semiconductor region 313 (part of the substrate 311) in which a channel is formed has a protruding shape. In addition, the conductive layer 316 is provided to cover the side surface and the top surface of the semiconductor region 313 with the insulating layer 315 therebetween. Note that a material adjusting the work function may be used for the conductive layer 316. The transistor 400 as described above is also referred to as a FIN-type transistor because it utilizes a protruding portion of a semiconductor substrate. Note that an insulator functioning as a mask for forming the protruding portion may be included in contact with an upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 400 illustrated in FIG. 19 is an example and the structure is not limited thereto; an appropriate transistor is used in accordance with a circuit configuration or a driving method.

Wiring layers provided with an interlayer film, a wiring, a plug, and the like may be provided between components. A plurality of wiring layers can be provided in accordance with design. In this specification and the like, a wiring and a plug electrically connected to the wiring may be a single component. That is, part of a conductor functions as a wiring in some cases and part of a conductor functions as a plug in other cases.

For example, an insulating layer 320, an insulating layer 322, an insulating layer 324, and an insulating layer 326 are sequentially stacked over the transistor 400 as interlayer films. A conductive layer 328, a conductive layer 330, and the like that are electrically connected to the conductive layer 352 are embedded in the insulating layer 320, the insulating layer 322, the insulating layer 324, and the insulating layer 326. Note that the conductive layer 328 and the conductive layer 330 function as a contact plug or a wiring.

Insulators functioning as interlayer films may also function as planarization films that cover uneven shapes therebelow. For example, a top surface of the insulating layer 322 may be subjected to CMP treatment or the like to have improved planarity.

A wiring layer may be provided over the insulating layer 326 and the conductive layer 330. For example, in FIG. 19, an insulating layer 350, an insulating layer 382, and an insulating layer 384 are stacked sequentially over the insulating layer 326 and the conductive layer 330. A conductive layer 386 is formed in the insulating layer 350, the insulating layer 382, and the insulating layer 384. The conductive layer 386 functions as a contact plug or a wiring. The conductive layer 386 is electrically connected to the conductive layer 352.

The structure described in this embodiment can be used in an appropriate combination with the structures described in the other embodiments.

### Embodiment 4

In this embodiment, a structure example in which the plurality of memory circuits 231 are arranged side by side in the same layer overlapping with the scan flip-flop 220 in one of the OSFFs 210 is described. In order to reduce repeated description, portions that are different from those in the other embodiments are mainly described in this embodiment. Thus, the other embodiments may be referred to for matters not described in this embodiment.

In the above embodiment, the structure example in which the plurality of memory circuits 231 are stacked in the Z direction in one of the OSFFs 210 is described. In the case where the area of the memory circuit 231 is much smaller than the area of the scan flip-flop 220, j memory circuits 231 (j is any one of integers greater than or equal to 2) can be arranged side by side on the X-Y plane in the same layer overlapping with the scan flip-flop 220.

In order to reduce the area of the memory circuit 231, VFETs are preferably used as the transistors included in the memory circuit 231. When the area of the memory circuit 231 is less than or equal to half, preferably less than or equal to ⅕, further preferably less than or equal to ⅛ of the area of the scan flip-flop 220, the plurality of memory circuits 231 are easily arranged side by side in the same layer overlapping with the scan flip-flop 220.

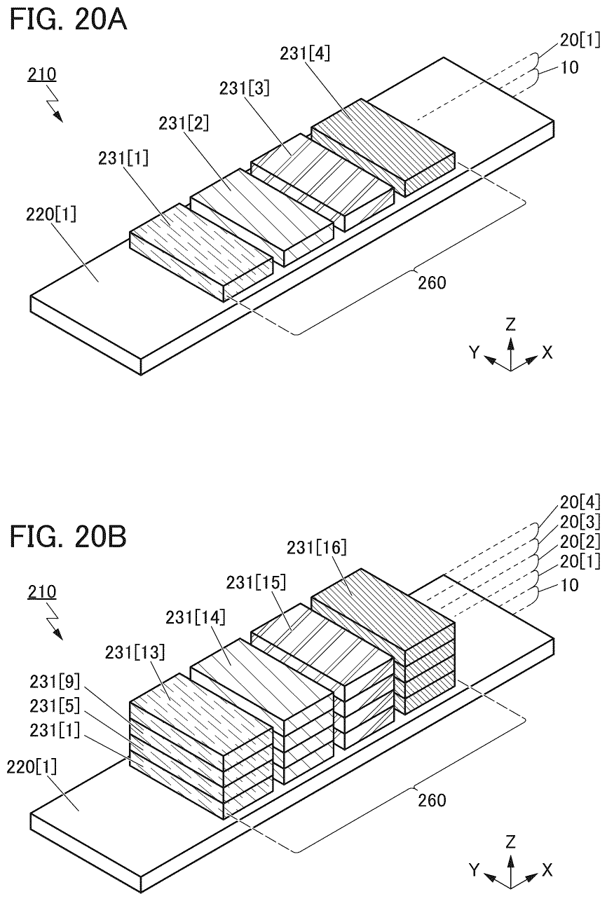

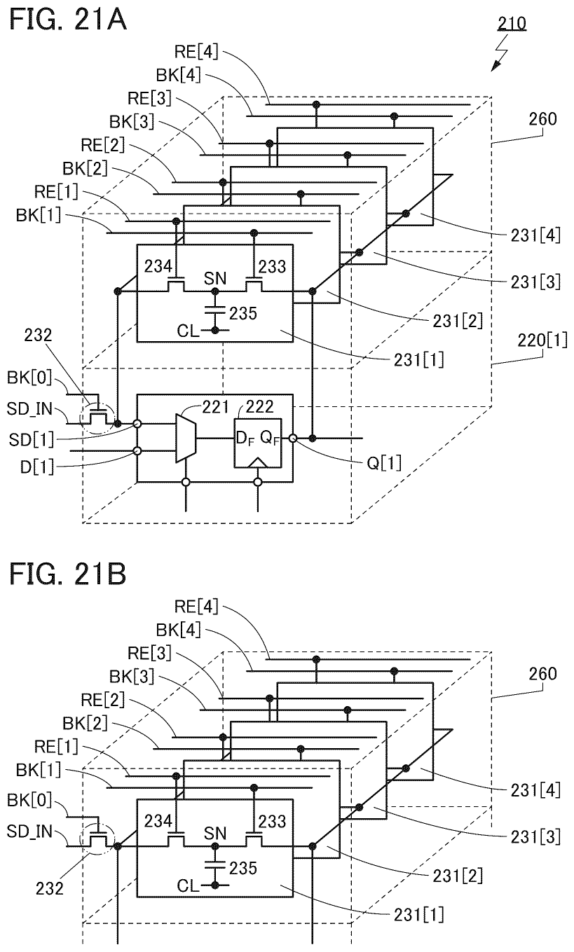

FIG. 20A is a perspective block diagram of the OSFF 210 in which the plurality of memory circuits 231 are arranged in parallel in the same layer overlapping with the scan flip-flop 220. FIG. 21A illustrates a circuit configuration example of the OSFF 210. FIG. 20A illustrates an example in which four memory circuits 231 (the memory circuit 231[1] to the memory circuit 231[4]) in the case where j is 4 are arranged in parallel over the scan flip-flop 220. The scan flip-flop 220 is formed in the layer 10, and all of the four memory circuits 231 are formed in the layer 20[1].

Alternatively, as illustrated in FIG. 20B, the memory circuits 231 may be stacked. FIG. 20B is a perspective block diagram illustrating an example in which the four memory circuits 231 are arranged in parallel in each of the layer 20[1] to the layer 20[4]. Thus, the OSFF 210 illustrated in FIG. 20B includes sixteen memory circuits 231 (the memory circuit 231[1] to the memory circuit 231[16]). The OSFF 210 illustrated in FIG. 20B is the OSFF 210 where k is 4 and j is 4.

When the plurality of memory circuits 231 are provided in one layer 20, a large number of memory circuits 231 can be provided with a small number of stacked layers. Furthermore, by reducing the number of stacked layers 20, the productivity of the OSFF 210 can be improved. Moreover, the productivity of the semiconductor device including the OSFF 210 is improved.

Note that the transistor 232 may be provided in the layer 10 or the layer 20 (see FIG. 21A and FIG. 21B). That is, the transistor 232 may be a Si transistor or may be an OS transistor.

As described above, when a VFET is used as the transistor included in the memory circuit 231, the area of the memory circuit 231 can be reduced. When the area of the memory circuit 231 is as it is, the number of transistors used in the memory circuit 231 can be increased. For example, when a plurality of VFETs are connected in parallel, the plurality of VFETs can function as one transistor having a large channel width W. In addition, with a photomask for forming the VFET, the capacitor 235 overlapping with the VFET when seen from the Z direction can also be formed.

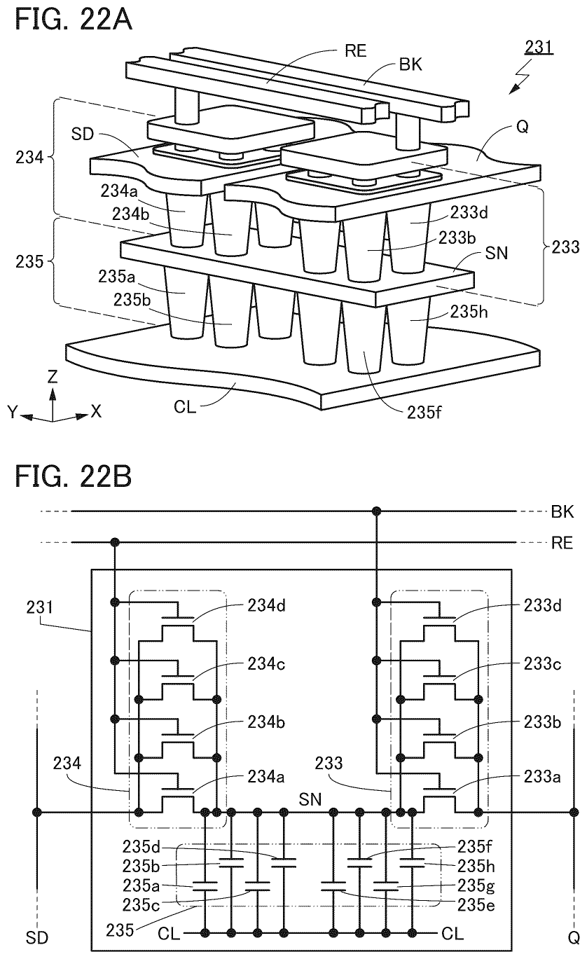

FIG. 22A is a schematic perspective view illustrating a structure example of the memory circuit 231. FIG. 22B is a circuit diagram of the memory circuit 231 illustrated in FIG. 22A. The memory circuit 231 illustrated in FIG. 22A and FIG. 22B includes eight transistors (a transistor 233a, a transistor 233b, a transistor 233c, a transistor 233d, a transistor 234a, a transistor 234b, a transistor 234c, and a transistor 234d). Moreover, the memory circuit 231 illustrated in FIG. 22A and FIG. 22B includes eight capacitors (a capacitor 235a, a capacitor 235b, a capacitor 235c, a capacitor 235d, a capacitor 235e, a capacitor 235f, a capacitor 235g, and a capacitor 235h).

The transistor 233a, the transistor 233b, the transistor 233c, and the transistor 233d are connected in parallel and function as one transistor 233. Sources of the transistor 233a, the transistor 233b, the transistor 233c, and the transistor 233d are electrically connected to each other, drains of the transistors are electrically connected to each other, and gates of the transistors are electrically connected to each other.

The transistor 234a, the transistor 234b, the transistor 234c, and the transistor 234d are connected in parallel and function as one transistor 234. Sources of the transistor 234a, the transistor 234b, the transistor 234c, and the transistor 234d are electrically connected to each other, drains of the transistors are electrically connected to each other, and gates of the transistors are electrically connected to each other.

The capacitor 235a, the capacitor 235b, the capacitor 235c, the capacitor 235d, the capacitor 235e, the capacitor 235f, the capacitor 235g, and the capacitor 235h are connected in parallel and function as one capacitor 235. Electrodes on one side of the capacitor 235a to the capacitor 235h are electrically connected to each other, and electrodes on the other side of the capacitor 235a to the capacitor 235h are electrically connected to each other.

As described above, when a plurality of transistors are connected in parallel, the plurality of transistors function as one transistor having a large channel width W. By increasing the channel width W of the transistor 233, the data writing speed to the node SN can be increased. By increasing the channel width W of the transistor 234, the data reading speed from the node SN can be increased. When a plurality of capacitors are connected in parallel, the capacitance value of the capacitor 235 increases, so that the data retention capability of the node SN can be increased.

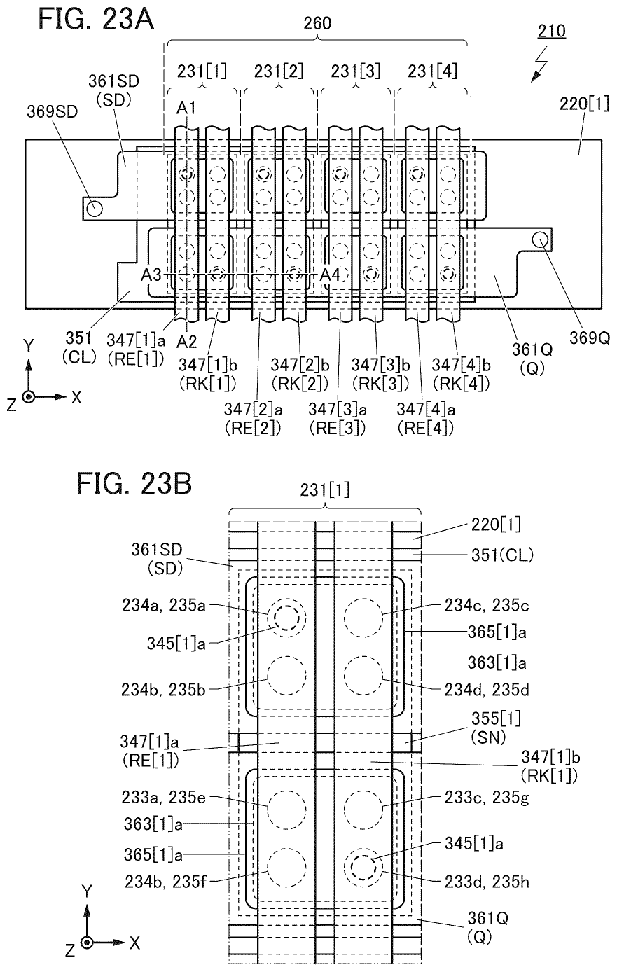

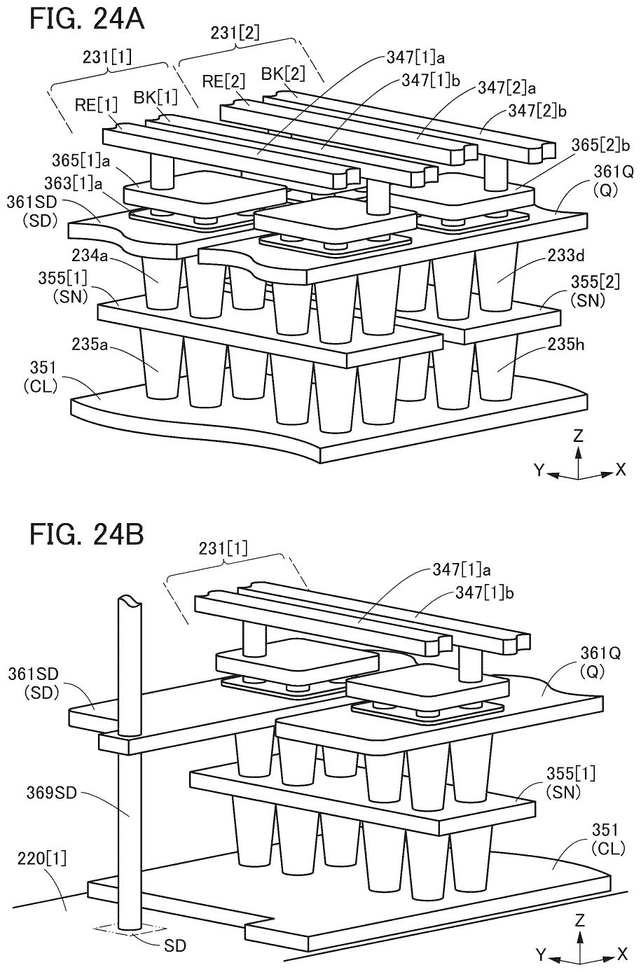

FIG. 23A is a plan view of the OSFF 210 in the case where the memory circuit 231 illustrated in FIG. 22A is used for the OSFF 210 illustrated in FIG. 20A. FIG. 23B is an enlarged plan view of the memory circuit 231[1]. FIG. 24A is a schematic perspective view of a region of the OSFF 210 in FIG. 23A including the memory circuit 231[1] and the memory circuit 231[2]. FIG. 24B is a schematic perspective view of a region of the OSFF 210 in FIG. 23A including the memory circuit 231[1] and a conductive layer 369SD.

In FIG. 23A, a conductive layer 361Q is electrically connected to the terminal Q of the OSFF 210 through a conductive layer 369Q. Note that it can also be said that the conductive layer 361Q and the conductive layer 369Q function as the terminal Q. A conductive layer 361SD is electrically connected to the terminal SD of the OSFF 210 through the conductive layer 369SD. Note that it can also be said that the conductive layer 361SD and the conductive layer 369SD function as the terminal Q.

The conductive layer 361Q and the conductive layer 361SD each extend in the X direction. In addition, the following layers extend in the Y direction; conductive layers 347 (a conductive layer 347[1]a, a conductive layer 347[2]a, a conductive layer 347[3]a, and a conductive layer 347[4]a) to which the signal RE is supplied and the conductive layers 347 (a conductive layer 347[1]b, a conductive layer 347[2]b, a conductive layer 347[3]b, and a conductive layer 347[4]b) to which the signal BK is supplied. That is, the conductive layer 347 extends in a direction intersecting with the conductive layer 361 (the conductive layer 361Q and the conductive layer 361SD).

The conductive layer 369Q and the conductive layer 369SD each extend in the Z direction (see FIG. 24B). That is, conductive layers 369 (the conductive layer 369Q and the conductive layer 369SD) extends in a direction intersecting with the conductive layer 347 and the conductive layer 361.

The conductive layer 369 functions as a contact plug, a through electrode (VIA), or a wiring. When the conductive layer 369Q extends in the Z direction, the conductive layer 361Q included in each of the stacked memory circuits 231 (see FIG. 20B) can be electrically connected to the terminal Q of the OSFF 210 through one conductive layer 369Q. When the conductive layer 369SD extends in the Z direction, the conductive layer 361SD included in each of the stacked memory circuits 231 can be electrically connected to the terminal SD of the OSFF 210 through one conductive layer 369SD.

For example, the signal RE[1] is supplied to the memory circuit 231[1] through the conductive layer 347[1]a, and the signal BK[1] is supplied to the memory circuit 231[1] through the conductive layer 347[1]b. The signal RE[2] is supplied to the memory circuit 231[2] through the conductive layer 347[2]a, and the signal BK[2] is supplied to the memory circuit 231[2] through the conductive layer 347[2]b. The signal RE[3] is supplied to the memory circuit 231[3] through the conductive layer 347[3]a, and the signal BK[3] is supplied to the memory circuit 231[3] through the conductive layer 347[3]b. The signal RE[4] is supplied to the memory circuit 231[4] through the conductive layer 347[4]a, and the signal BK[4] is supplied to the memory circuit 231[4] through the conductive layer 347[4]b.

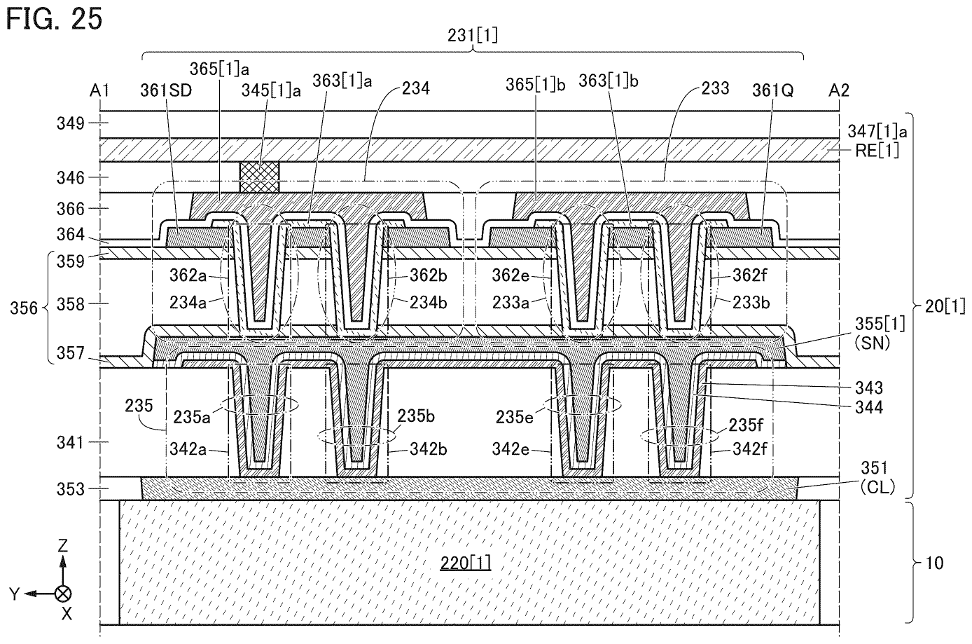

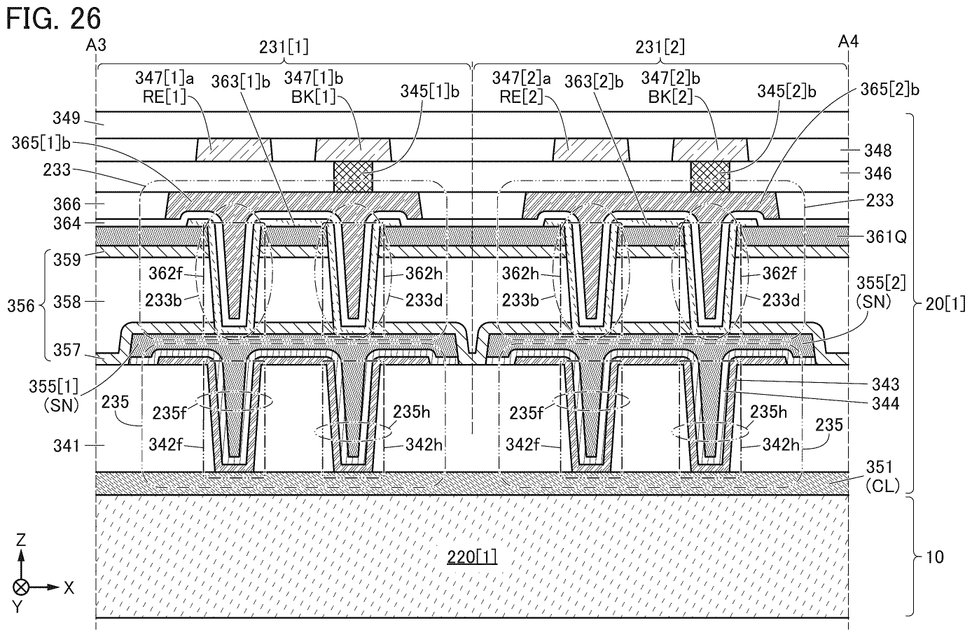

Next, an example of a stacked-layer structure of a semiconductor device of one embodiment of the present invention illustrated in FIG. 23A will be described. FIG. 25 is a cross-sectional view of a portion indicated by the dashed-dotted line A1-A2 in FIG. 23A. FIG. 26 is a cross-sectional view of a portion indicated by dashed-dotted line A3-A4 in FIG. 23A. In this embodiment, an example of a stacked-layer structure of a portion indicated by the dashed-dotted line A1-A2 in FIG. 23A and an example of a stacked-layer structure of a portion indicated by the dashed-dotted line A3-A4 in FIG. 23A are described.

FIG. 25 is a diagram including a cross-sectional structure of the memory circuit 231[1], and FIG. 26 is a diagram including cross-sectional structures of the memory circuit 231[1] and the memory circuit 231[2]. The semiconductor device includes the insulating layer 353 (not illustrated in FIG. 26) and the conductive layer 351 embedded in the insulating layer 353 over the scan flip-flop 220 provided in the layer 10. The conductive layer 351 functions as the wiring CL. Note that the top surfaces of the insulating layer 353 and the conductive layer 351 are preferably level with or substantially level with each other (in the Z direction) by a CMP method or the like.

The semiconductor device includes an insulating layer 341 over the insulating layer 353 and the conductive layer 351. In the insulating layer 353, an opening 342 (an opening 342a to an opening 342h) is provided in a region overlapping with part of the conductive layer 351. Note that the opening 342c, the opening 342d, and the opening 342g are not illustrated in FIG. 25 and FIG. 26.

The semiconductor device includes a conductive layer 343 over the insulating layer 341. The insulating layer 341 includes a region overlapping with the opening 342 (the opening 342a to the opening 342h). In each of the opening 342a to the opening 342h, the conductive layer 343 includes a region overlapping with the bottom portion of the opening and a region overlapping with the side surface of the opening (the side surface of the insulating layer 341). The conductive layer 343 and the conductive layer 351 are electrically connected to each other at the bottom portion of each of the opening 342a to the opening 342h.

The semiconductor device includes, over the conductive layer 343, an insulating layer 344 that covers the conductive layer 343. The insulating layer 344 includes a region overlapping with the side surface of the opening 342 with the conductive layer 343 therebetween and a region overlapping with the bottom surface of the opening 342 with the conductive layer 343 therebetween. The semiconductor device includes a plurality of conductive layers 355 over the insulating layer 344. The conductive layer 355 includes a region overlapping with the side surface of the opening 342 with the insulating layer 344 and the conductive layer 343 therebetween and a region overlapping with the bottom surface of the opening 342 with the insulating layer 344 and the conductive layer 343 therebetween.

In the opening 342a, a region where the conductive layer 343 and the conductive layer 355 (a conductive layer 355[1] or a conductive layer 355[2]) overlap with each other with the insulating layer 344 therebetween functions as the capacitor 235a. In the opening 342b, a region where the conductive layer 343 and the conductive layer 355 overlap with each other with the insulating layer 344 therebetween functions as the capacitor 235b. In the opening 342c, a region where the conductive layer 343 and the conductive layer 355 overlap with each other with the insulating layer 344 therebetween functions as the capacitor 235c. In the opening 342d, a region where the conductive layer 343 and the conductive layer 355 overlap with each other with the insulating layer 344 therebetween functions as the capacitor 235d. In the opening 342e, a region where the conductive layer 343 and the conductive layer 355 overlap with each other with the insulating layer 344 therebetween functions as the capacitor 235e. In the opening 342f, a region where the conductive layer 343 and the conductive layer 355 overlap with each other with the insulating layer 344 therebetween functions as the capacitor 235f. In the opening 342g, a region where the conductive layer 343 and the conductive layer 355 overlap with each other with the insulating layer 344 therebetween functions as the capacitor 235g. In the opening 342h, a region where the conductive layer 343 and the conductive layer 355 overlap with each other with the insulating layer 344 therebetween functions as the capacitor 235h.

The capacitor 235a to the capacitor 235h are connected in parallel and function as one capacitor 235. For the insulating layer 344 functioning as the dielectric of the capacitor 235, a material with a high relative dielectric constant (also referred to as a “high-k material”) may be used. A ferroelectric may be used for the insulating layer 344 functioning as the dielectric of the capacitor 235.

The conductive layer 355 functions as the node SN. The conductive layer 355 is provided independently for each memory circuit 231. For example, the conductive layer 355[1] included in the memory circuit 231[1] functions as the node SN that retains data written to the memory circuit 231[1], and the conductive layer 355[2] included in the memory circuit 231[2] functions as the node SN that retains data written to the memory circuit 231[2].

The semiconductor device includes the insulating layer 357 over the insulating layer 341 and the conductive layer 355, the insulating layer 358 over the insulating layer 357, and the insulating layer 359 over the insulating layer 358. Note that the insulating layer 357, the insulating layer 358, and the insulating layer 359 are collectively referred to as the insulating layer 356 or a spacer layer in some cases. The conductive layer 361 (the conductive layer 361SD and the conductive layer 361Q) is provided over the insulating layer 359.

In a region overlapping with part of the conductive layer 355, the opening 362 (an opening 362a to an opening 362h) is provided in the conductive layer 361, the insulating layer 359, the insulating layer 358, and the insulating layer 357. Note that the opening 362c, the opening 362d, and the opening 362g are not illustrated in FIG. 25 and FIG. 26.

In FIG. 25, the semiconductor device includes a semiconductor layer 363[1]a that covers the opening 362a, the opening 362b, the opening 362c (not illustrated), and the opening 362d (not illustrated). The semiconductor layer 363[1]a includes a region overlapping with the bottom portions of the opening 362a, the opening 362b, the opening 362c, and the opening 362d and a region overlapping with the side surfaces of the openings.

In FIG. 25 and FIG. 26, the semiconductor device includes a semiconductor layer 363[1]b that covers the opening 362e, the opening 362f, the opening 362g (not illustrated), and the opening 362h. The semiconductor layer 363[1]b includes a region overlapping with the bottom portions of the opening 362e, the opening 362f, the opening 362g, and the opening 362h and a region overlapping with the side surfaces of the openings.

The semiconductor device includes the insulating layer 364 over the insulating layer 359, the conductive layer 361, and the semiconductor layer 363 (the semiconductor layer 363[1]a, the semiconductor layer 363[1]b, a semiconductor layer 363[2]a (not illustrated), and a semiconductor layer 363[2]b), and includes the conductive layer 365 (a conductive layer 365[1]a, a conductive layer 365[1]b, a conductive layer 365[2]a (not illustrated), and a conductive layer 365[2]b) over the insulating layer 364. The semiconductor device includes the insulating layer 366 over the insulating layer 364. Top surfaces of the conductive layer 365 and the insulating layer 366 are preferably level with or substantially level with each other (in the Z direction).

A region including the opening 362a functions as the transistor 234a, and a region including the opening 362b functions as the transistor 234b. A region including the opening 362c functions as the transistor 234c (not illustrated), and a region including the opening 362d functions as the transistor 234d (not illustrated). The transistor 234a, the transistor 234b, the transistor 234c, and the transistor 234d are connected in parallel and function as one transistor 234 having a large channel width W.

A region including the opening 362e functions as the transistor 233a, and a region including the opening 362f functions as the transistor 233b. A region including the opening 362g functions as the transistor 233c (not illustrated), and a region including the opening 362h functions as the transistor 233d (not illustrated). The transistor 233a, the transistor 233b, the transistor 233c, and the transistor 233d are connected in parallel and function as one transistor 233 having a large channel width W.

Note that the above embodiment can be referred to for the description of the transistor 233 and the transistor 234. Thus, the description of the transistor 233 and the transistor 234 is omitted in this embodiment.

The semiconductor device includes a conductive layer 345 over the conductive layer 365. FIG. 25 illustrates a conductive layer 345[1]a over the conductive layer 365[1]a, and FIG. 26 illustrates a conductive layer 345[1]b over the conductive layer 365[1]b and a conductive layer 345[2]b over the conductive layer 365[2]b. The semiconductor device includes an insulating layer 346 over the insulating layer 366 and the conductive layer 365. Top surfaces of the conductive layer 345 and the insulating layer 346 are preferably level with or substantially level with each other (in the Z direction).

The semiconductor device includes a plurality of the conductive layers 347 over the conductive layer 345 and the insulating layer 346. In FIG. 25 and FIG. 26, the conductive layer 347[1]a, the conductive layer 347[1]b, the conductive layer 347[2]a, and the conductive layer 347[2]b are illustrated as the plurality of conductive layers 347. The conductive layer 347[1]a is electrically connected to the conductive layer 365[1]a through the conductive layer 345[1]a. The conductive layer 347[1]b is electrically connected to the conductive layer 365[1]b through the conductive layer 345[1]b. The conductive layer 347[2]a is electrically connected to the conductive layer 365[2]a (not illustrated) through a conductive layer 345[2]a (not illustrated). The conductive layer 347[2]b is electrically connected to the conductive layer 365[2]b through the conductive layer 345[2]b.

The semiconductor device includes an insulating layer 348 over the insulating layer 346. Top surfaces of the conductive layer 347 and the insulating layer 348 are preferably level with or substantially level with each other (in the Z direction). The semiconductor device includes an insulating layer 349 over the conductive layer 347 and the insulating layer 348.

As described above, the conductive layer 361SD functions as the terminal SD, and the conductive layer 361Q functions as the terminal Q. The signal RE[1] is supplied to the memory circuit 231[1] through the conductive layer 347[1]a, and the signal BK[1] is supplied to the memory circuit 231[1] through the conductive layer 347[1]b. The signal RE[2] is supplied to the memory circuit 231[2] through the conductive layer 347[2]a, and the signal BK[2] is supplied to the memory circuit 231[2] through the conductive layer 347[2]b.

The structure described in this embodiment can be used in an appropriate combination with the structures described in the other embodiments.

### Embodiment 5

In this embodiment, application examples of the semiconductor device of one embodiment of the present invention will be described.

The semiconductor device according to one embodiment of the present invention can be used not only for the CPU but also for a variety of electronic components. For example, the semiconductor device can be applied to a register of a microprocessor such as a DSP (Digital Signal Processor) or a GPU (Graphics Processing Unit). The microprocessor may be constructed with a PLD (Programmable Logic Device) such as an FPGA (Field Programmable Gate Array) or an FPAA (Field Programmable Analog Array).

Thus, the semiconductor device of one embodiment of the present invention can be applied to, for example, a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

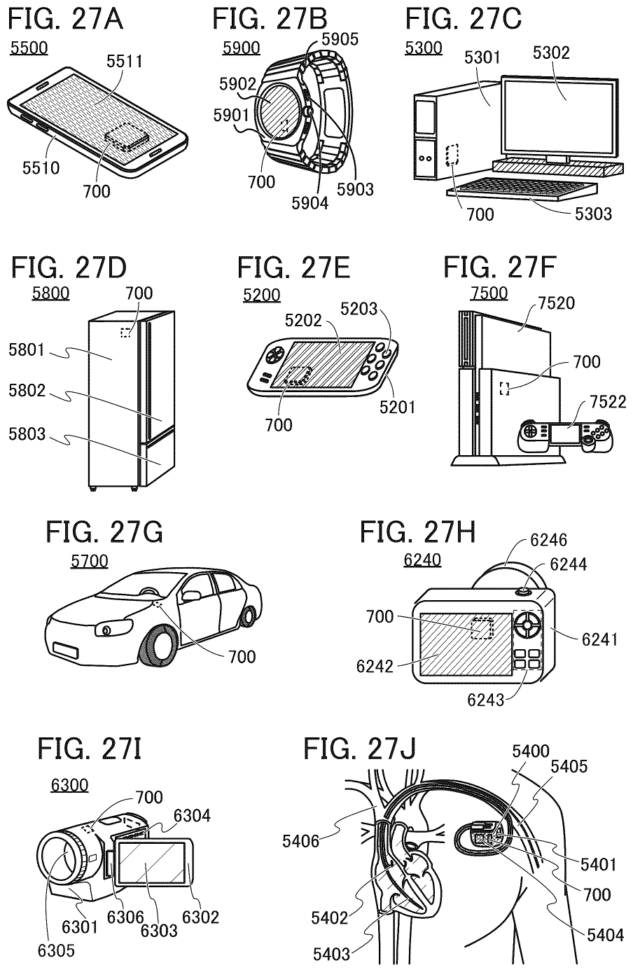

An example of an electronic device including the semiconductor device of one embodiment of the present invention is described. Note that FIG. 27A to FIG. 27J each illustrate a state where an electronic component 700 including the semiconductor device is included in an electronic device.

### Mobile Phone

An information terminal 5500 illustrated in FIG. 27A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

The information terminal 5500 can quickly respond to interrupt processing or the like that occurs at the time of executing an application by applying the semiconductor device of one embodiment of the present invention.

### Wearable Terminal

FIG. 27B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can quickly respond to interrupt processing or the like that occurs at the time of executing an application by applying the semiconductor device of one embodiment of the present invention to the wearable terminal.

### Information Terminal

FIG. 27C illustrates a desktop information terminal 5300. The desktop information terminal 5300 includes a main body 5301 of the information terminal, a display portion 5302, and a keyboard 5303.

Like the information terminal 5500 and the like described above, the desktop information terminal 5300 can quickly respond to interrupt processing or the like that occurs at the time of executing an application by applying the semiconductor device of one embodiment of the present invention to the desktop information terminal 5300.

Note that although the smartphone, the wearable terminal, and the desktop information terminal are respectively illustrated in FIG. 27A to FIG. 27C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### Household Appliance

FIG. 27D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal or the like via the Internet or the like.

Like the information terminal 5500 and the like described above, the electric refrigerator-freezer 5800 can quickly respond to interrupt processing or the like that occurs at the time of executing an application by applying the semiconductor device of one embodiment of the present invention to the electric refrigerator-freezer 5800.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### Game Machine

FIG. 27E illustrates a portable game machine 5200 as an example of a game machine. The portable game machine 5200 includes a housing 5201, a display portion 5202, a button 5203, and the like.

In addition, FIG. 27F illustrates a stationary game machine 7500 as another example of a game machine. The stationary game machine 7500 includes a main body 7520 and a controller 7522. Note that the controller 7522 can be connected to the main body 7520 with or without a wire. Although not illustrated in FIG. 27F, the controller 7522 can include a display portion that displays a game image, and an input interface besides a button, such as a touch panel, a stick, a rotating knob, or a sliding knob, for example. The shape of the controller 7522 is not limited to that illustrated in FIG. 27F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display device such as a television device, a personal computer display, a game display, or a head-mounted display.

The semiconductor device described in the above embodiment is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, the semiconductor device described in the above embodiment is employed for the portable game machine 5200 or the stationary game machine 7500, so that it is possible to respond to interrupt processing or the like quickly that occurs during game play.

As an example of a game machine, FIG. 27E illustrates a portable game machine. In addition, FIG. 27F illustrates a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), a throwing machine for batting practice installed in sports facilities, and the like.

### Moving Vehicle

The semiconductor device described in the above embodiment can be used for an automobile, which is a moving vehicle, and around the driver's seat in an automobile.

FIG. 27G illustrates an automobile 5700, which is an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a display device showing the above information may be provided around the driver's seat.

In particular, the display device can compensate for the view obstructed by a pillar or the like, blind areas for the driver's seat, and the like by displaying a video from an imaging device (not illustrated) provided for the automobile 5700, which can increase safety. That is, display of an image from an imaging device provided on the outside of the automobile 5700 can fill in blind areas and increase safety.

By applying the semiconductor device of one embodiment of the present invention, the moving object can quickly respond to interrupt processing or the like that occurs at the time of running a moving object such as emergency stop treatment.

Note that although an automobile is described above as an example of a moving vehicle, the moving vehicle is not limited to an automobile. Examples of moving vehicles include a train, a monorail train, a ship, and a flying object (a helicopter, an unmanned aircraft (a drone), an airplane, and a rocket).

### Camera

The semiconductor device described in the above embodiment can be employed for a camera.

FIG. 27H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, although the lens 6246 of the digital camera 6240 is detachable from the housing 6241 for replacement, the lens 6246 may be undetachable. In addition, the digital camera 6240 can be additionally equipped with a stroboscope, a viewfinder, or the like.

When the semiconductor device described in the above embodiment is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### Video Camera

The semiconductor device described in the above embodiment can be employed for a video camera.

FIG. 27I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

The semiconductor device described in the above embodiment is employed for the video camera 6300, whereby the video camera 6300 can have low power consumption. Furthermore, a time for filming can be extended owing to low power consumption. Moreover, heat generation from a circuit can be reduced owing to low power consumption; thus, the influence of heat generation on the circuit itself, a peripheral circuit, and a module can be reduced.

### ICD

The semiconductor device described in the above embodiment can be applied to an implantable cardioverter defibrillator (ICD).

FIG. 27J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

The antenna 5404 can receive electric power, and the battery 5401 is charged with the electric power. Furthermore, when the ICD main unit 5400 includes a plurality of batteries, safety can be increased. Specifically, even when some of the batteries in the ICD main unit 5400 are dead, the other batteries can work properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

The semiconductor device described in the above embodiment is employed for the ICD main unit 5400, whereby the ICD main unit 5400 can have low power consumption. Furthermore, the storage battery can be reduced in size and weight owing to low power consumption. Moreover, heat generation of the ICD main unit 5400 can be reduced owing to low power consumption; thus, a load on the human body can be reduced.

### Computer

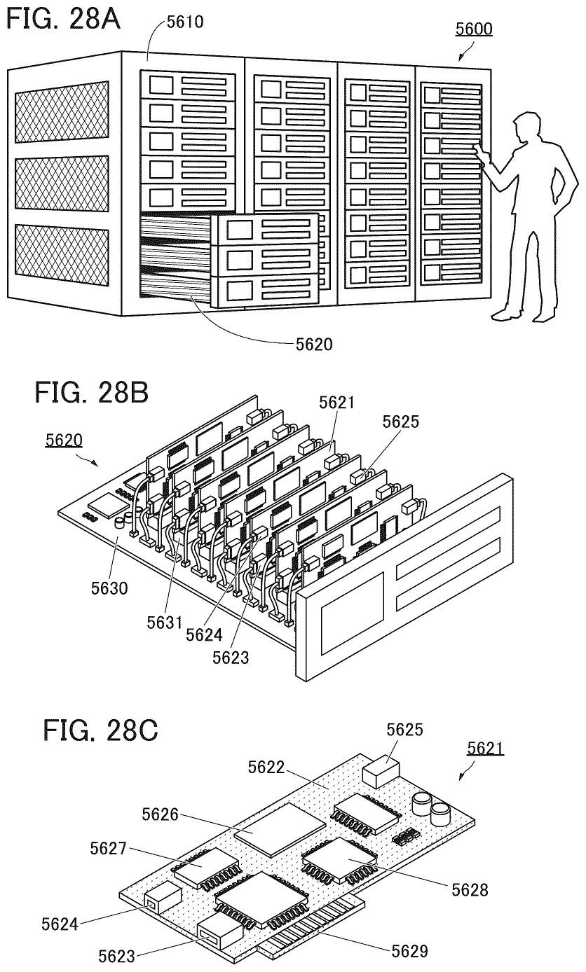

A computer 5600 illustrated in FIG. 28A is an example of a large computer (a supercomputer) mainly used for scientific computation. In scientific computation, an enormous amount of arithmetic operation needs to be processed at high speed; hence, power consumption is high and chips generate a large amount of heat. For example, a data center including a plurality of super computers uses an enormous amount of digital data. Specifically, the amount of digital data in the world is expected to exceed 10²⁴ (yota) bytes or 10³⁰ (quetta) bytes.

When the semiconductor device of one embodiment of the present invention is employed for the computer 5600, a supercomputer with low power consumption can be achieved. Moreover, heat generation from a circuit can be reduced owing to low power consumption; thus, the influence of heat generation on the circuit itself, a peripheral circuit, and a module can be reduced. When the semiconductor device of one embodiment of the present invention is employed, a supercomputer with low power consumption can be achieved. This can be expected to reduce the amount of digital data in the world to make a significant contribution to global warming countermeasures.

In the computer 5600, a plurality of rack mount computers 5620 are stored in a rack 5610. The computer 5620 can have a structure in a perspective view illustrated in FIG. 28B, for example. In FIG. 28B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 28C is an example of a processing board provided with a CPU, a GPU, a storage device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 28C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 700 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device.

The computer 5600 can also function as a parallel computer. When the computer 5600 is used as a parallel computer, large-scale computation necessary for artificial intelligence learning and inference can be performed, for example.

The above electronic device or the like can quickly respond to interrupt processing or the like that occurs at the time of executing an application by using the semiconductor device of one embodiment of the present invention. In addition, a reduction in power consumption of the electronic device can be achieved by using the semiconductor device of one embodiment of the present invention. Heat generation from a circuit can be reduced owing to low power consumption; thus, the influence of heat generation on the circuit itself, a peripheral circuit, and a module can be reduced. Furthermore, the use of the semiconductor device of one embodiment of the present invention can achieve an electronic device that operates stably even in a high temperature environment. Thus, the reliability of the electronic device can be increased.

The structure described in this embodiment can be used in an appropriate combination with the structures described in the other embodiments.

### Embodiment 6

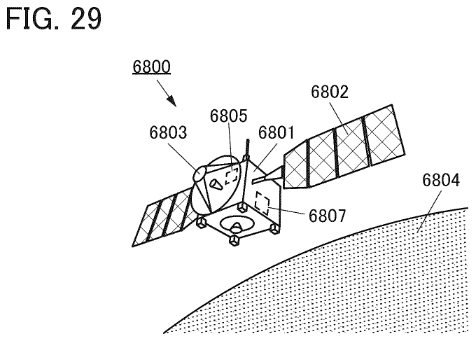

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, OS transistors can be suitably used in outer space. In this embodiment, a specific example of using the semiconductor device of one embodiment of the present invention in a device for space will be described with reference to FIG. 29.

FIG. 29 illustrates an artificial satellite 6800 as an example of a device for space. The artificial satellite 6800 includes a body 6801, a solar panel 6802, an antenna 6803, a secondary battery 6805, and a control device 6807. In FIG. 29, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

The structure described in this embodiment can be used in an appropriate combination with the structures described in the other embodiments.

### REFERENCE NUMERALS

100: semiconductor device, 110: CPU core, 111: arithmetic portion, 120: bus, 130: PMU, 131: control circuit, 140: input/output IF, 150: cache memory, 160: state control portion, 200: register group, 201: register, 210: OSFF, 220: scan flip-flop, 221: selector, 222: flip-flop, 230: data retention circuit, 231: memory circuit, 232: transistor, 233: transistor, 234: transistor, 235: capacitor, 250: flip-flop group, 255: memory unit, 260: bank memory

1. A semiconductor device comprising:
a flip-flop group comprising n flip-flops;
a first memory unit comprising n memory circuits provided over the flip-flop group; and
a second memory unit comprising p memory circuits provided over the first memory unit,
wherein the flip-flops each comprise a first transistor comprising silicon in a semiconductor layer where a channel is formed,
wherein each of the n memory circuits and the p memory circuits comprises a second transistor comprising an oxide semiconductor in a semiconductor layer where a channel is formed,
wherein when data retained in the flip-flop group is n-bit first data, the semiconductor device is configured to retain the first data in the first memory unit in a first operation,
wherein when data retained in the flip-flop group is p-bit second data, the semiconductor device is configured to retain the second data in the second memory unit in a second operation,
wherein n is an integer greater than or equal to 2, and
wherein p is an integer greater than or equal to 1 and less than n.

2. The semiconductor device according to claim 1,
wherein each of the n memory circuits and the p memory circuits comprises the two second transistors and one capacitor.

3. The semiconductor device according to claim 2,
wherein the two second transistors each comprises a region overlapping with the capacitor.

4. The semiconductor device according to claim 1,
wherein the second transistor is a vertical-channel transistor.

5. The semiconductor device according to claim 1,
wherein the first operation is an operation relating to power gating, and
wherein the second operation is an operation relating to interrupt processing.
